(19) United States
(12) Patent Application Publication
(10) Pub. No.: US 2026/0157192 A1
(43) Pub. Date: Jun. 4, 2026

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Koki SAMURA, Tokyo (JP); Haruki MURAKAMI, Tokyo (JP)

(73) Assignee: Mitsubishi Electric Corporation, Tokyo (JP)

(21) Appl. No.: 19/177,435

(22) Filed: Apr. 11, 2025

(30) Foreign Application Priority Data
Jul. 5, 2024 (JP) 2024-108604

(51) Int. Cl. H10W 70/40; H10W 40/20; H10W 70/04; H10W 90/10

(52) U.S. Cl. CPC H10W 70/466; H10W 70/041; H10W 90/10; H10W 40/235

(57) ABSTRACT

At least one semiconductor module is disposed over an upper surface of a base plate and has a control terminal and a first output terminal extending horizontally. A pedestal is disposed over the upper surface of the base plate and has a first surface facing the upper surface of the base plate and a second surface being opposite the first surface and having a first protrusion. A metal terminal has a first bonded portion bonded to the first output terminal of the at least one semiconductor module and has a first mating hole mating with the first protrusion of the pedestal.

### BACKGROUND

### Technical Field

The present disclosure relates to semiconductor devices and methods of manufacturing the semiconductor devices and, in particular, to a semiconductor device having a metal terminal and a method of manufacturing the semiconductor device.

### Description of the Background Art

Japanese Patent Application Laid-Open No. 2022-006876 discloses a semiconductor device. The semiconductor device includes: a semiconductor module having power terminals and control terminals; a capacitor having connection terminals; and connecting members. The connecting members electrically connect and mechanically couple the power terminals and the connection terminals. The connecting members are thus bonded to the power terminals. The connecting members are bonded by laser welding after end portions of the connecting members are set on surfaces of the power terminals.

Metal terminals, such as the above-mentioned connecting members, and output terminals, such as the above-mentioned power terminals of the semiconductor module, are required to be arranged at suitable relative positions in an XY direction as a direction perpendicular to a Z direction while being overlaid with each other in the Z direction before being bonded together. Excessive misalignment of this arrangement in the XY direction sometimes unintentionally brings the metal terminals and the control terminals of the semiconductor module excessively close to each other. When bonding is performed with such arrangement, an insulating distance sometimes cannot be secured between the metal terminals electrically connected to the output terminals of the semiconductor module and the control terminals of the semiconductor module. This insufficient insulating distance might cause generation of an undesirable leakage current or an undesirable electrical short between the output terminals and the control terminals of the semiconductor module, for example.

### SUMMARY

The present disclosure has been conceived to solve a problem as described above, and it is an object of the present disclosure to provide a semiconductor device and a method of manufacturing the semiconductor device enabling stable securement of an insulating distance between a metal terminal electrically connected to an output terminal of a semiconductor module and a control terminal of the semiconductor module.

A semiconductor device according to one aspect of the present disclosure includes: a base plate having an upper surface; at least one semiconductor module disposed over the upper surface of the base plate and having a control terminal and a first output terminal, the first output terminal extending horizontally; a pedestal disposed over the upper surface of the base plate and having a first surface and a second surface, the first surface facing the upper surface of the base plate, the second surface being opposite the first surface and having a first protrusion; and a metal terminal having a first bonded portion bonded to the first output terminal of the at least one semiconductor module and having a first mating hole mating with the first protrusion of the pedestal.

A semiconductor device according to another aspect of the present disclosure includes: a base plate having an upper surface; a semiconductor module disposed over the upper surface of the base plate and having a control terminal and an output terminal, the output terminal having a root portion extending horizontally and a tip portion extending to have a smaller width than the root portion, the output terminal being bent between the root portion and the tip portion so that the tip portion extends non-horizontally; and a metal terminal having a bonded portion bonded to the root portion of the output terminal of the semiconductor module, the metal terminal having a mating hole mating with the tip portion of the output terminal.

A semiconductor device according to yet another aspect of the present disclosure includes: a base plate having an upper surface; a semiconductor module disposed over the upper surface of the base plate and having a control terminal and an output terminal; and a metal terminal having a bonded portion bonded to the output terminal of the semiconductor module, wherein the output terminal and the metal terminal have a mating structure including a cutout in plan view and a protrusion mating with the cutout, and one of the output terminal and the metal terminal has the cutout and the other one of the output terminal and the metal terminal has the protrusion.

A method of manufacturing a semiconductor device according to yet another aspect of the present disclosure includes: disposing a semiconductor module over an upper surface of a base plate, the semiconductor module having a control terminal and an output terminal, the output terminal extending horizontally; disposing a metal terminal so that the metal terminal spans between the output terminal of the semiconductor module and a pedestal having a protrusion, the metal terminal being disposed so that a portion of the metal terminal overlaps the output terminal and a mating hole of the metal terminal mates with the protrusion of the pedestal; bonding the portion of the metal terminal to the output terminal; and removing the pedestal after bonding the portion of the metal terminal.

According to the semiconductor device according to each of the above-mentioned aspects, misalignment of the metal terminal in an in-plane direction is suppressed. An insulating distance can thus stably be secured between the metal terminal electrically connected to the output terminal and the control terminal.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view schematically showing a configuration of a semiconductor device according to Embodiment 1;

FIG. 2 is a cross-sectional view taken along the line II-II of FIG. 1;

FIG. 3 is a plan view schematically showing a configuration of a metal terminal in FIG. 1;

FIG. 4 is a plan view illustrating a configuration of a semiconductor device according to a comparative example;

FIG. 5 is a cross-sectional view taken along the line V-V of FIG. 4;

FIG. 6 is a plan view schematically showing a configuration of a semiconductor device according to Embodiment 2;

FIG. 7 is a plan view schematically showing a configuration of a metal terminal in FIG. 6;

FIG. 8 is a plan view schematically showing a configuration of a semiconductor device according to Embodiment 3;

FIG. 9 is a plan view schematically showing a configuration of a metal terminal in FIG. 8;

FIG. 10 is a plan view schematically showing a configuration of a semiconductor device according to Embodiment 4;

FIG. 11 is a plan view schematically showing a configuration of a metal terminal in FIG. 10;

FIG. 12 is a plan view schematically showing a configuration of a semiconductor device according to Embodiment 5;

FIG. 13 is a plan view schematically showing a configuration of a metal terminal in FIG. 12;

FIG. 14 is a partial plan view illustrating an example of mating of a first protrusion with a first mating hole in the semiconductor device according to Embodiment 5;

FIG. 15 is a partial plan view illustrating an example of mating of a first protrusion with a first mating hole in the semiconductor device according to Embodiment 4;

FIG. 16 is a partial plan view illustrating an example of mating of a partially missing first protrusion with the first mating hole in the semiconductor device according to Embodiment 5;

FIG. 17 is a partial plan view illustrating an example of mating of a partially missing first protrusion with the first mating hole in the semiconductor device according to Embodiment 4;

FIG. 18 is a plan view schematically showing a configuration of a semiconductor device according to Embodiment 6;

FIG. 19 is a plan view schematically showing a configuration of a metal terminal in FIG. 18;

FIG. 20 is a plan view schematically showing a configuration of a semiconductor device according to Embodiment 7;

FIG. 21 is a plan view schematically showing a configuration of a metal terminal in FIG. 20;

FIG. 22 is a plan view schematically showing a configuration of a semiconductor device according to Embodiment 8;

FIG. 23 is a cross-sectional view taken along the line XXIII-XXIII of FIG. 22;

FIG. 24 is a plan view schematically showing a configuration of a semiconductor device according to Embodiment 9;

FIG. 25 is a cross-sectional view taken along the line XXV-XXV of FIG. 24;

FIG. 26 is a plan view schematically showing a first step of a method of manufacturing a semiconductor device according to Embodiment 9;

FIG. 27 is a cross-sectional view taken along the line XXVII-XXVII of FIG. 26;

FIG. 28 is a plan view schematically showing a second step of the method of manufacturing the semiconductor device according to Embodiment 9;

FIG. 29 is a cross-sectional view taken along the line XXIX-XXIX of FIG. 26;

FIG. 30 is a plan view schematically showing a configuration of a semiconductor device according to Embodiment 10;

FIG. 31 is a plan view schematically showing a configuration of a metal terminal in FIG. 30;

FIG. 32 is a plan view schematically showing a configuration of a semiconductor module in FIG. 30;

FIG. 33 is a plan view schematically showing a configuration of a semiconductor device according to Embodiment 11;

FIG. 34 is a cross-sectional view taken along the line XXXIV-XXXIV of FIG. 33;

FIG. 35 is a partial bottom view of the semiconductor device in FIG. 33;

FIG. 36 is a plan view schematically showing a configuration of a semiconductor module in FIG. 33; and

FIG. 37 is a partial plan view schematically showing a configuration of a semiconductor device according to Embodiment 12.

### DESCRIPTION OF THE PREFERRED EMBODIMENTS

Embodiments will be described below based on the accompanying drawings. An XYZ Cartesian coordinate system is shown in each of the drawings to facilitate understanding of a directional relationship among the drawings. In relation to the coordinate system, a view corresponding to an XY plane is also referred to as a “plan view”, a direction corresponding to an XY in-plane direction is also referred to as an “in-plane direction”, a direction corresponding to a Z direction in the coordinate system is also referred to as a “height direction”, and a surface facing in a +Z direction is also referred to as an “upper surface”, but these phrases do not imply any relationship with a direction of gravity unless accompanied by specific description on gravity. A phrase “orthogonal” herein means substantially orthogonal and means intersecting at 90°±5°, for example. A phrase “parallel” herein means substantially parallel, and a difference within a range of ±5° is ignored, for example. An alloy having metallic nature is considered as metal. The same or corresponding portions bear the same reference signs in the drawings referred to below, and description thereof is not repeated.

### Embodiment 1

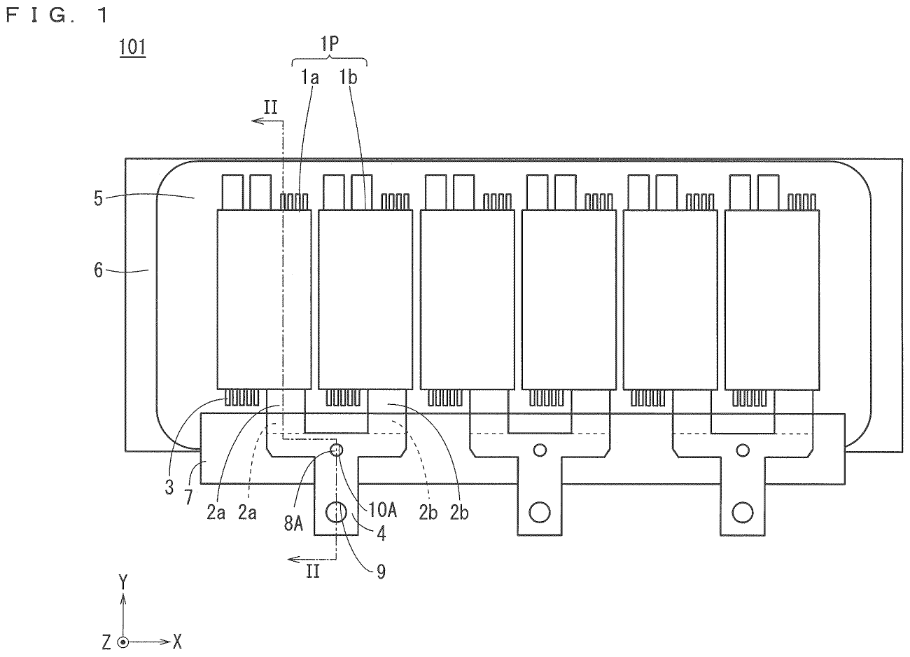

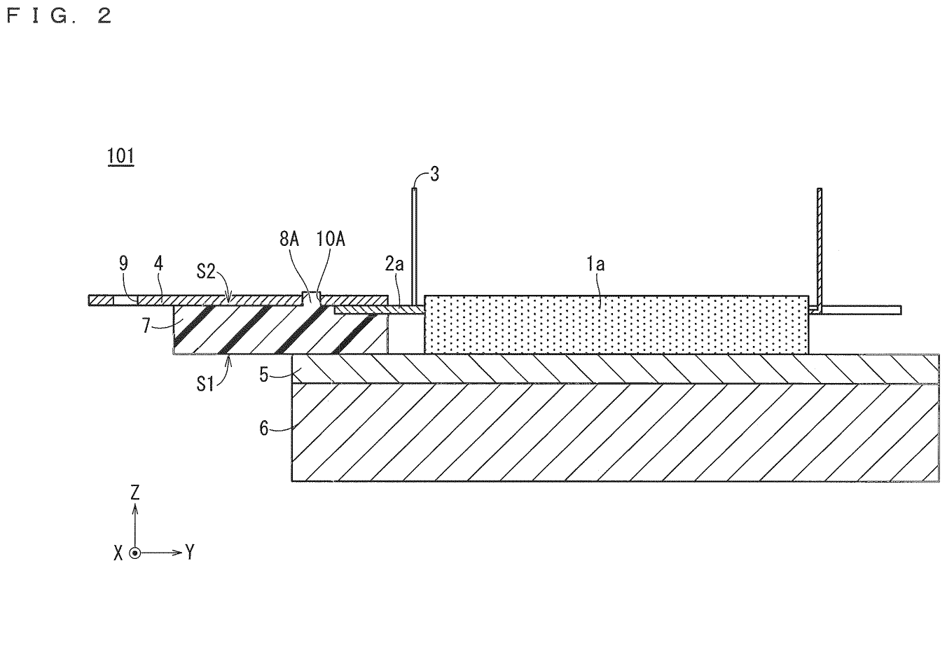

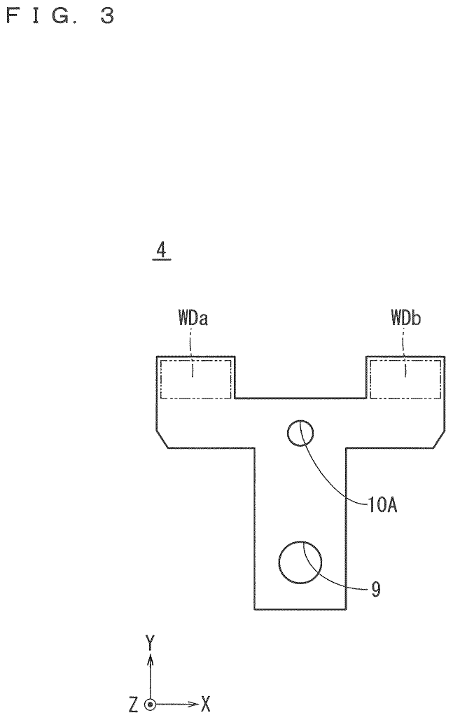

FIG. 1 is a plan view schematically showing a configuration of a semiconductor device 101 according to Embodiment 1. FIG. 2 is a cross-sectional view taken along the line II-II of FIG. 1. FIG. 3 is a plan view schematically showing a configuration of a metal terminal 4 in FIG. 1. FIG. 3 shows a bonded portion WDa and a bonded portion WDb to respectively be bonded to an output terminal 2a and an output terminal 2b (FIG. 1) by phantom lines (alternate long and two short dashes lines).

The semiconductor device 101 includes at least one semiconductor module 1a. Specifically, the semiconductor device 101 may include at least one semiconductor module set 1P, and the semiconductor module set 1P includes a pair of the semiconductor module 1a and a semiconductor module 1b arranged adjacent to each other in the XY in-plane direction. In an example shown in FIG. 1, the semiconductor module 1a and the semiconductor module 1b are adjacent to each other in a direction parallel to an X direction. The semiconductor module 1a and the semiconductor module 1b may have a substantially common structure. In the example shown in FIG. 1, the semiconductor device 101 includes three semiconductor module sets 1P.

The semiconductor module 1a and the semiconductor module 1b each have control terminals 3. The semiconductor module 1a and the semiconductor module 1b may each include a semiconductor switching element (not illustrated) having a gate electrically connected to the control terminals 3, and the semiconductor switching element is a metal-insulator-semiconductor field-effect transistor (MISFET) or an insulated-gate bipolar transistor (IGBT), for example.

The semiconductor module 1a has an output terminal 2a (a first output terminal) to output power controlled by a control signal to the control terminals 3. The output terminal 2a extends horizontally from an insulating package (a portion shown by a rectangle in FIG. 1) of the semiconductor module 1a. In other words, the output terminal 2a extends in the XY in-plane direction orthogonal to the Z direction corresponding to a direction of the thickness of the semiconductor device 101. The output terminal 2a may extend from the insulating package along a direction of extension parallel to a-Y direction. Specifically, in plan view, the insulating package has one side along the X direction, and a direction orthogonal to this side, that is, the Y direction, corresponds to the direction of extension of the output terminal 2a. Both of the output terminal 2a and the control terminals 3 of the semiconductor module 1a may extend from the above-mentioned one side of the insulating package. Similarly, the semiconductor module 1b has an output terminal 2b (a second output terminal) to output power controlled by an input signal to the control terminals 3, and the output terminal 2b extends from an insulating package of the semiconductor module 1b.

The semiconductor device 101 further includes a base plate 5 for dissipation of heat from the semiconductor module 1a and the semiconductor module 1b. Referring to FIG. 2, the base plate 5 has an upper surface and a lower surface. The semiconductor module 1a and the semiconductor module 1b are arranged over the upper surface of the base plate 5. A cooling mechanism 6 may be mounted to the lower surface of the base plate 5 and is a water cooling jacket, for example.

The semiconductor device 101 further includes a pedestal 7. The pedestal 7 is formed of an insulator, and the insulator is an insulating resin, for example. The pedestal 7 is disposed over the upper surface of the base plate 5. Specifically, the pedestal 7 has a lower surface S1 (a first surface) facing the upper surface of the base plate 5 and an upper surface S2 (a second surface opposite the first surface). The pedestal 7 and the base plate 5 are fixed to each other by a fastening member, for example. The fastening member may include a nut embedded in the pedestal 7 and a screw mating with the nut, for example. The upper surface S2 of the pedestal 7 has a protrusion 8A (first protrusion). The protrusion 8A and the other portion of the pedestal 7 may integrally be formed seamlessly.

The semiconductor device 101 further includes at least one metal terminal 4. The metal terminal 4 may be disposed for each semiconductor module set 1P, in other words, for each pair of the semiconductor module 1a and the semiconductor module 1b. In the example shown in FIG. 1, three metal terminals 4 are arranged in one-to-one correspondence with three semiconductor module sets 1P.

The metal terminal 4 (FIG. 3) has the bonded portion WDa (a first bonded portion) bonded to the output terminal 2a (FIG. 1) of the semiconductor module 1a. The metal terminal 4 may further have the bonded portion WDb (a second bonded portion) bonded to the output terminal 2b of the semiconductor module 1b (FIG. 1). To enable such bonding, the metal terminal 4 may have an extending portion (a lower portion in FIG. 3) extending in a direction parallel to the direction of extension of the output terminal 2a (Y direction) and a branching portion (an upper portion in FIG. 3) having a shape branching from the extending portion to the output terminal 2a and the output terminal 2b. A step of bonding the bonded portion WDa and the bonded portion WDb of the metal terminal 4 respectively to the output terminal 2a of the semiconductor module 1a and the output terminal 2b of the semiconductor module 1b may be performed by laser welding. The bonding step and a step of disposing the metal terminal 4 so that the metal terminal 4 overlaps the output terminal 2a and the output terminal 2b prior to the bonding step may be performed with arrangement in which a −Z direction is the direction of gravity in FIG. 2.

The metal terminal 4 has a portion overlapping the pedestal 7. In the portion, the metal terminal 4 has a mating hole 10A (first mating hole) mating with the protrusion 8A of the pedestal 7. The protrusion 8A has a shape corresponding to a shape of the mating hole 10A. The shape may be a circular shape as illustrated in FIG. 1 in Embodiment 1. In plan view, the mating hole 10A is located inside the base plate 5 in the example shown in FIG. 1 but may be located off the base plate 5 instead. In an example shown in FIG. 2, the protrusion 8A has a greater dimension than the metal terminal 4 in the height direction. In other words, the protrusion 8A has a greater thickness than the metal terminal 4. In another example, the protrusion 8A may have the same thickness as or a smaller thickness than the metal terminal 4.

The metal terminal 4 bonded to the output terminal 2a of the semiconductor module 1a is to electrically connect the output terminal 2a and a wiring member (not illustrated) connected to any load. The load is a motor, for example. When the metal terminal 4 is bonded to the output terminal 2b of the semiconductor module 1b, the wiring member is to be electrically connected not only to the output terminal 2a but also to the output terminal 2b. The metal terminal 4 may have a portion located off any of the output terminal 2a, the output terminal 2b, and the pedestal 7 in plan view. The portion is to be used to mount the metal terminal 4 to the wiring member. The metal terminal 4 may have a threaded hole 9 for convenience in mounting.

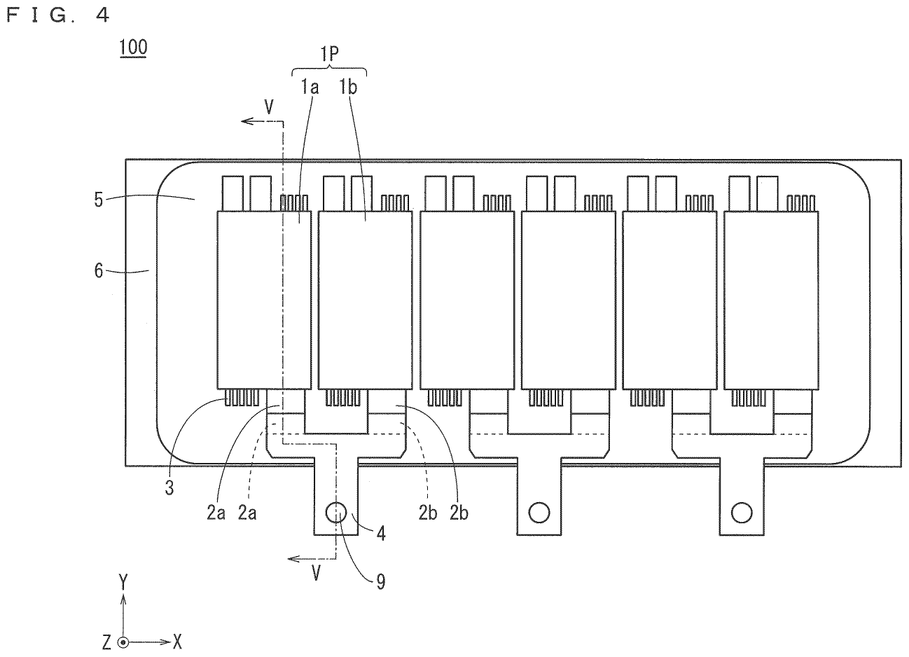

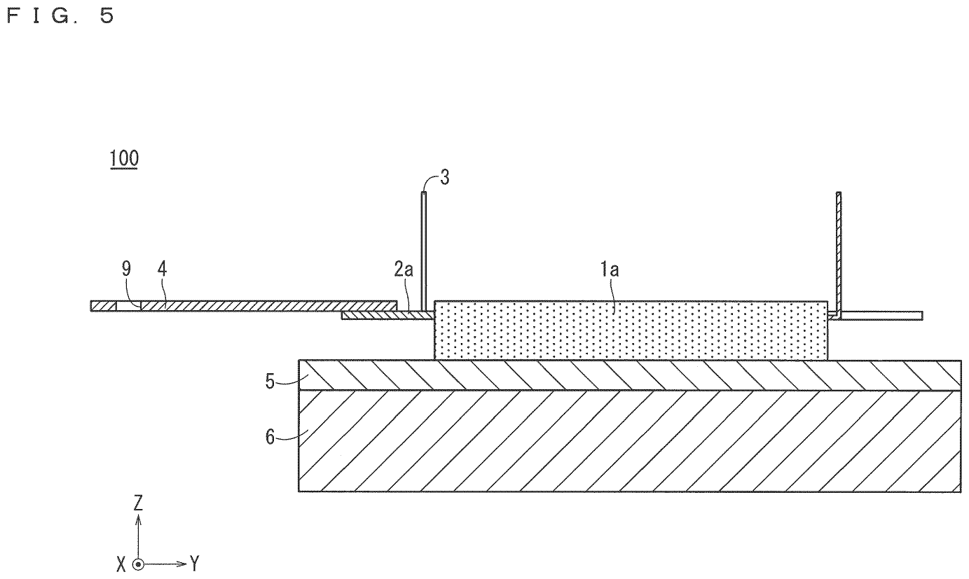

FIG. 4 is a plan view illustrating a configuration of a semiconductor device 100 according to a comparative example. FIG. 5 is a cross-sectional view taken along the line V-V of FIG. 4. In contrast to the semiconductor device 101 (FIGS. 1 and 2: Embodiment 1), the semiconductor device 100 does not include the pedestal 7.

The metal terminal 4 and the output terminal 2a are required to be arranged at suitable relative positions in an XY direction (the in-plane direction) while being overlaid with each other in the Z direction (height direction) before being bonded together. In the comparative example, when the metal terminal 4 is disposed prior to bonding, no particular structure to dispose the metal terminal 4 at a correct position in design with respect to the output terminal 2a is provided. This arrangement thus sometimes has excessive misalignment in the XY direction. As a result, the metal terminal 4 and the control terminal 3 of the semiconductor module 1a are sometimes unintentionally brought excessively close to each other. When bonding is performed with such arrangement, an insulating distance sometimes cannot be secured between the metal terminal 4 electrically connected to the output terminal 2a of the semiconductor module 1a and the control terminal 3 of the semiconductor module 1a. An insufficient insulating distance might cause generation of an undesirable leakage current or an undesirable electrical short, for example.

In particular, when the metal terminal 4 is to be bonded to each of the output terminal 2a and the output terminal 2b, the metal terminal 4 is required to be aligned with both of the output terminal 2a and the output terminal 2b. Even if alignment with one of them is sufficient, when alignment with the other one of them is insufficient, the metal terminal 4 can be brought excessively close to the control terminal 3 of the semiconductor module 1a or the semiconductor module 1b. It is thus more difficult to secure alignment accuracy of the metal terminal 4 in this case compared with a case where the metal terminal 4 is bonded only to the output terminal 2a.

According to Embodiment 1, the metal terminal 4 has the mating hole 10A mating with the protrusion 8A of the pedestal 7. The position of the mating hole 10A of the metal terminal 4 is thereby defined in the in-plane direction. Misalignment of the metal terminal 4 in the in-plane direction is thus suppressed. An insulating distance can thus stably be secured between the metal terminal 4 electrically connected to the output terminal 2a and the control terminal 3. While it is more difficult to secure alignment accuracy of the metal terminal 4 when the metal terminal 4 is required to be aligned with both of the output terminal 2a and the output terminal 2b in bonding the metal terminal 4, easy securement of the accuracy is facilitated according to Embodiment 1.

### Embodiment 2

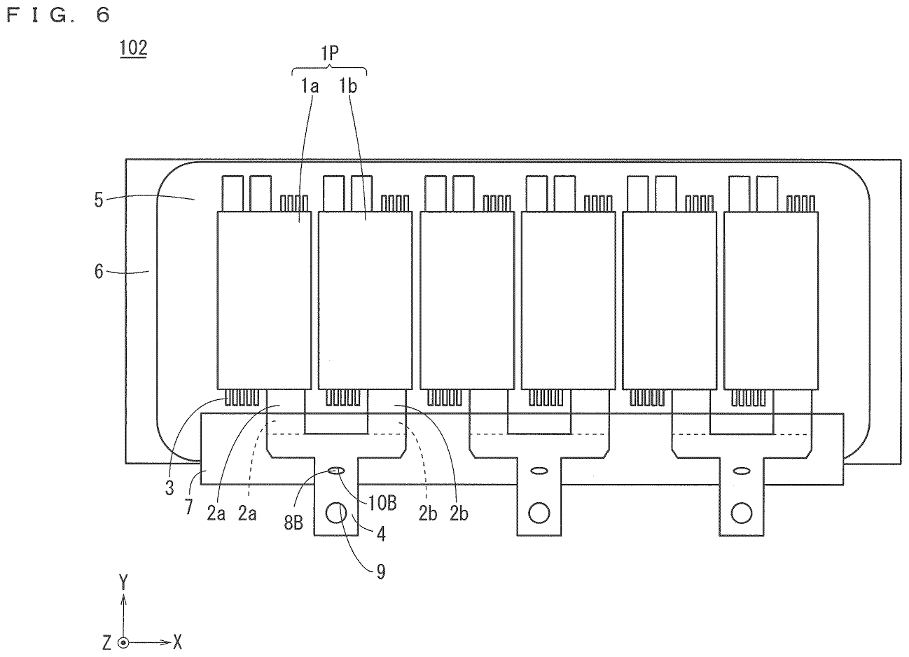

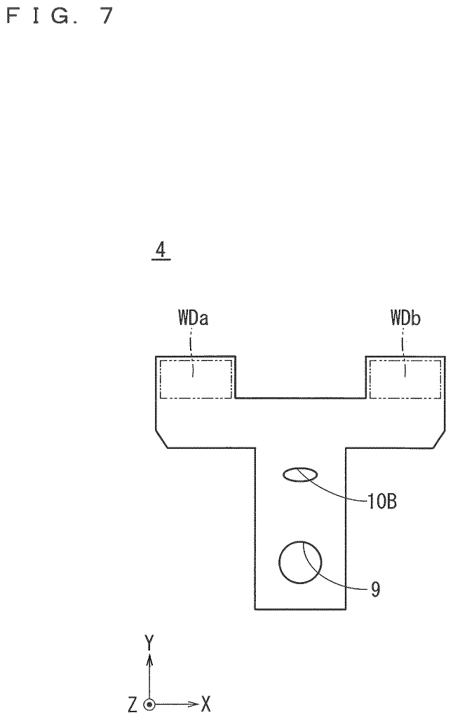

FIG. 6 is a plan view schematically showing a configuration of a semiconductor device 102 according to Embodiment 2. FIG. 7 is a plan view schematically showing a configuration of a metal terminal 4 in FIG. 6. FIG. 7 shows a bonded portion WDa and a bonded portion WDb to respectively be bonded to an output terminal 2a and an output terminal 2b (FIG. 6) by phantom lines (alternate long and two short dashes lines). In plan view, a protrusion 8B (the first protrusion) of the pedestal 7 has a shape corresponding to a shape of a mating hole 10B (the first mating hole) of the metal terminal 4. The mating hole 10B has an elliptical shape having a major axis. As illustrated in FIG. 6, the major axis may extend along an orthogonal direction (X direction) orthogonal to the direction of extension of the output terminal 2a (Y direction). A configuration other than the above-mentioned configuration is substantially the same as the above-mentioned configuration according to Embodiment 1, so that the same or corresponding components bear the same reference signs, and description thereof is not repeated.

According to Embodiment 2, the protrusion 8B of the pedestal 7 has the shape corresponding to the shape of the mating hole 10B of the metal terminal 4, and the mating hole 10B has the elliptical shape having the major axis. Misalignment of the metal terminal 4 in a direction of rotation around the protrusion 8B is thereby suppressed. An insulating distance can thus more stably be secured between the metal terminal 4 electrically connected to the output terminal 2a and the control terminal 3. While it is more difficult to secure alignment accuracy of the metal terminal 4 when the metal terminal 4 is required to be aligned with both of the output terminal 2a and the output terminal 2b in bonding the metal terminal 4, easier securement of the accuracy is facilitated according to Embodiment 2.

As a modification, the mating hole 10B and the protrusion 8B may each have a rectangular shape having a longer side in place of the elliptical shape having the major axis. The longer side may extend along the orthogonal direction (X direction) orthogonal to the direction of extension of the output terminal 2a (Y direction). Misalignment of the metal terminal 4 in the direction of rotation around the first protrusion is suppressed also in this modification.

### Embodiment 3

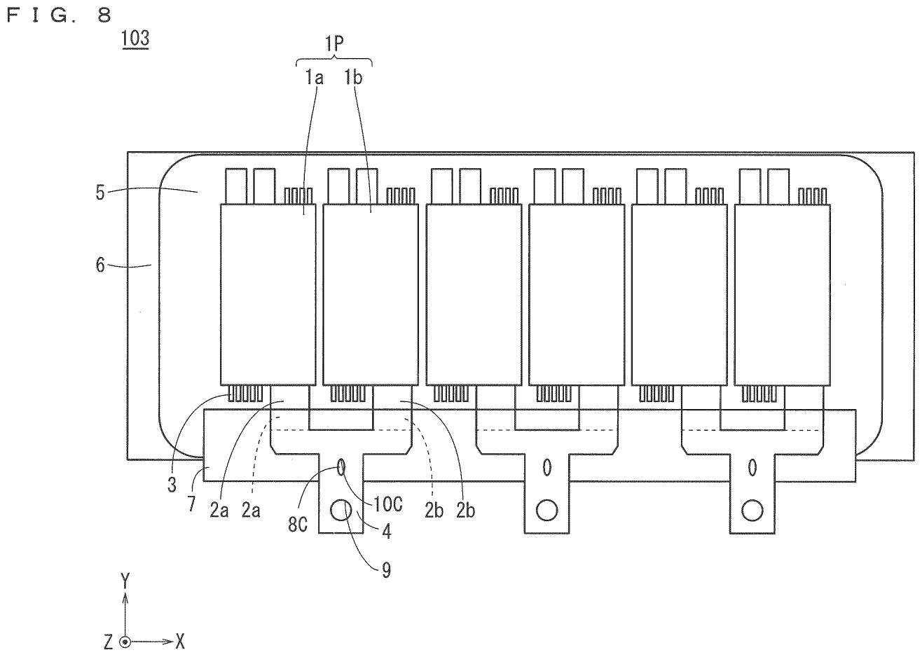

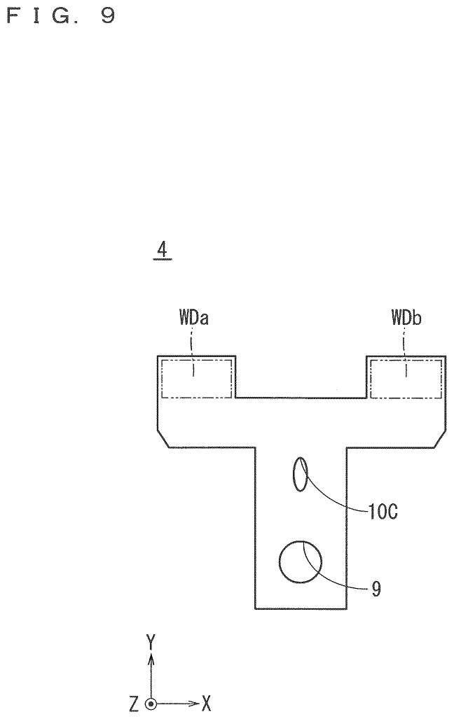

FIG. 8 is a plan view schematically showing a configuration of a semiconductor device 103 according to Embodiment 3. FIG. 9 is a plan view schematically showing a configuration of a metal terminal 4 in FIG. 8. FIG. 9 shows a bonded portion WDa and a bonded portion WDb to respectively be bonded to an output terminal 2a and an output terminal 2b (FIG. 8) by phantom lines (alternate long and two short dashes lines). In plan view, a protrusion 8C (the first protrusion) of the pedestal 7 has a shape corresponding to a shape of a mating hole 10C (the first mating hole) of the metal terminal 4. The mating hole 10C has an elliptical shape having a major axis along the direction parallel to the direction of extension of the output terminal 2a (Y direction). A configuration other than the above-mentioned configuration is substantially the same as the above-mentioned configuration according to Embodiment 1, so that the same or corresponding components bear the same reference signs, and description thereof is not repeated.

According to Embodiment 3, an effect of preventing misalignment of the metal terminal 4 in the direction of rotation can be obtained as in Embodiment 2 described above. Furthermore, according to Embodiment 3, the major axis of the elliptical shape of the mating hole 10C of the metal terminal 4 extends along the direction parallel to the direction of extension of the output terminal 2a (Y direction). An extent of interference of the mating hole 10C with a flow of a current along the direction of extension of the output terminal 2a (Y direction) in the metal terminal 4 is thus reduced compared with a case where the major axis extends along the other directions. Deterioration of electrical characteristics of the metal terminal 4 attributable to the mating hole 10C can thereby be reduced. For example, inductance of the metal terminal 4 can be reduced, or an allowable current amount can be increased.

### Embodiment 4

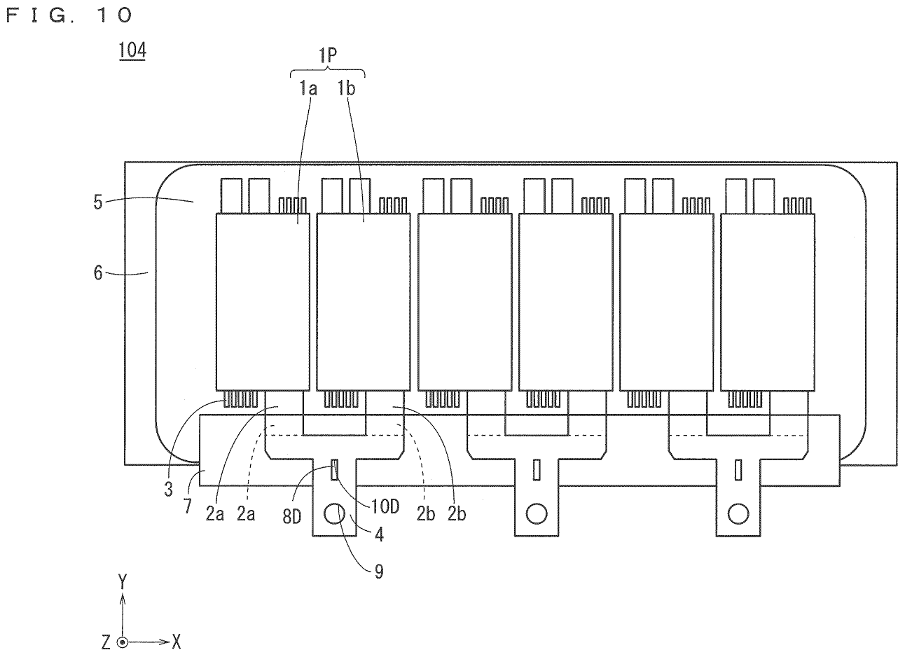

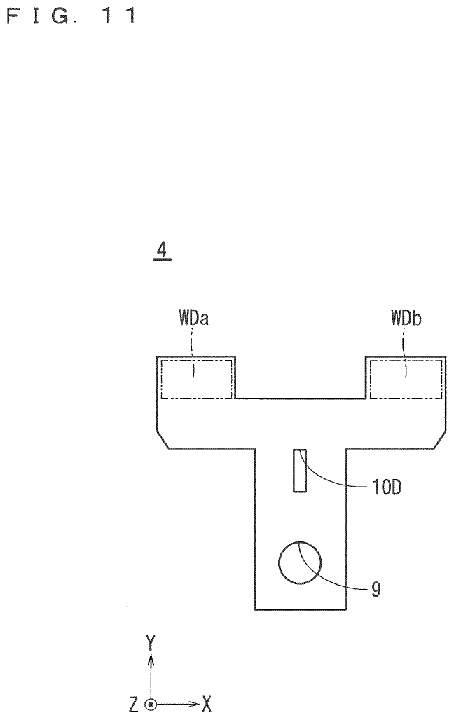

FIG. 10 is a plan view schematically showing a configuration of a semiconductor device 104 according to Embodiment 4. FIG. 11 is a plan view schematically showing a configuration of a metal terminal 4 in FIG. 10. FIG. 11 shows a bonded portion WDa and a bonded portion WDb to respectively be bonded to an output terminal 2a and an output terminal 2b (FIG. 10) by phantom lines (alternate long and two short dashes lines). In plan view, a protrusion 8D (the first protrusion) of the pedestal 7 has a shape corresponding to a shape of a mating hole 10D (the first mating hole) of the metal terminal 4. The mating hole 10D has a rectangular shape having a longer side extending along the direction parallel to the direction of extension of the output terminal 2a (Y direction). A configuration other than the above-mentioned configuration is substantially the same as the above-mentioned configuration according to Embodiment 3, so that the same or corresponding components bear the same reference signs, and description thereof is not repeated. According to Embodiment 4, a similar effect to that obtained in Embodiment 3 described above can be obtained.

### Embodiment 5

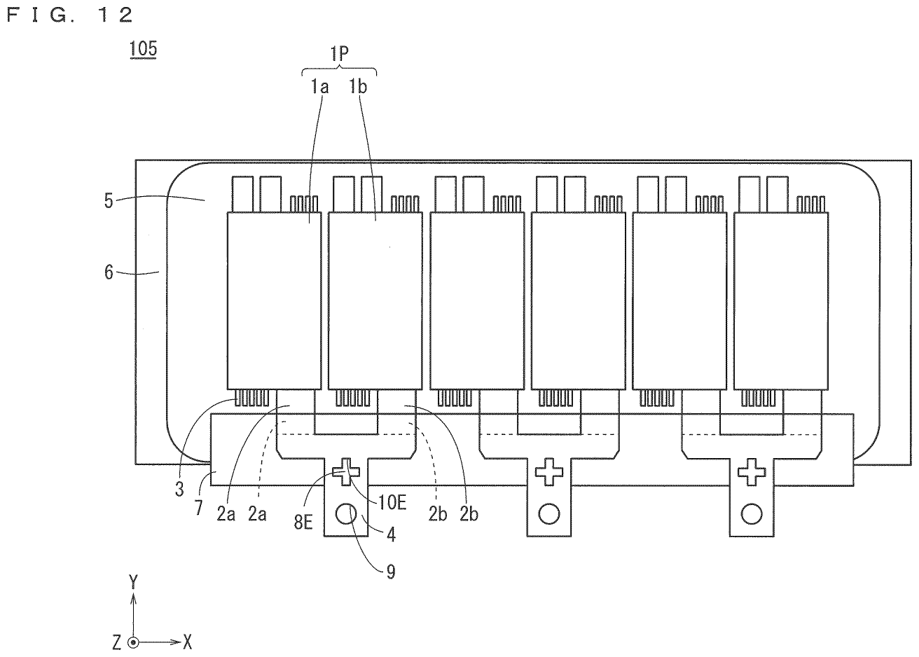

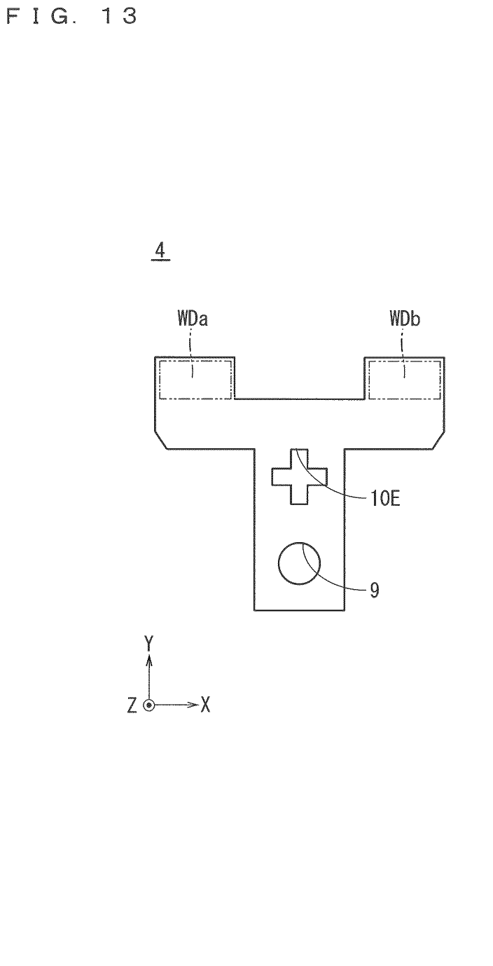

FIG. 12 is a plan view schematically showing a configuration of a semiconductor device 105 according to Embodiment 5. FIG. 13 is a plan view schematically showing a configuration of a metal terminal 4 in FIG. 12. FIG. 13 shows a bonded portion WDa and a bonded portion WDb to respectively be bonded to an output terminal 2a and an output terminal 2b (FIG. 12) by phantom lines (alternate long and two short dashes lines). In plan view, a protrusion 8E (the first protrusion) of the pedestal 7 has a shape corresponding to a shape of a mating hole 10E (the first mating hole) of the metal terminal 4. The mating hole 10E has a cruciform shape. A configuration other than the above-mentioned configuration is substantially the same as the above-mentioned configuration according to Embodiment 1, so that the same or corresponding components bear the same reference signs, and description thereof is not repeated.

According to Embodiment 5, an effect of suppressing misalignment of the metal terminal 4 in a direction of rotation around the protrusion 8E can be obtained similarly to that obtained in Embodiments 2 to 4 described above. Furthermore, according to Embodiment 5, the number of points of contact between the protrusion 8E and the mating hole 10E when misalignment in the direction of rotation is to occur increases. The above-mentioned effect can thus further be increased. The effect is less likely to be impaired even when a portion at a point of contact as described above is missing from any cause. These additional effects will specifically be described below.

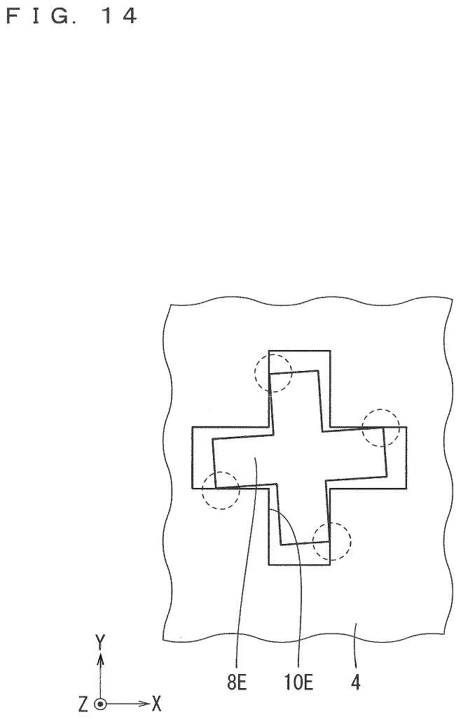

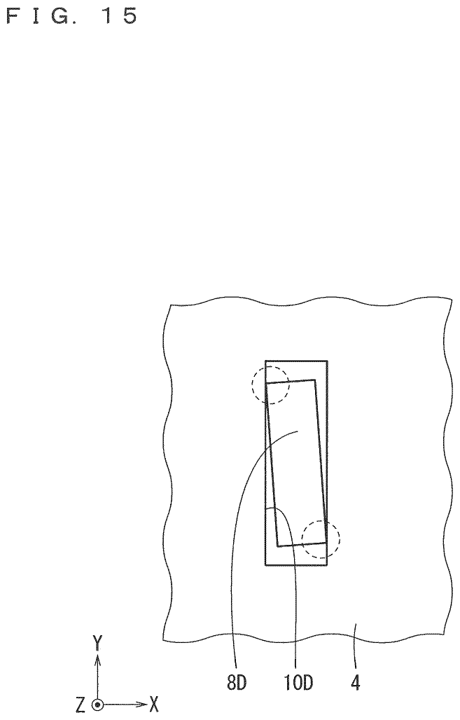

FIG. 14 is a partial plan view illustrating an example of mating of the protrusion 8E with the mating hole 10E in the semiconductor device 105 according to Embodiment 5. FIG. 15 is a partial plan view illustrating an example of mating of the protrusion 8D with the mating hole 10D in the semiconductor device 104 according to Embodiment 4 described above. In these figures, circles indicated by dashed lines show points of contact between the protrusion of the pedestal 7 and the mating hole of the metal terminal 4 when misalignment of the metal terminal 4 in a direction of clockwise rotation is to occur around the protrusion 8E (or the protrusion 8D). Two points can contribute to prevention of rotation in FIG. 15 (Embodiment 4), whereas four points can contribute to prevention of rotation in FIG. 14 (Embodiment 5).

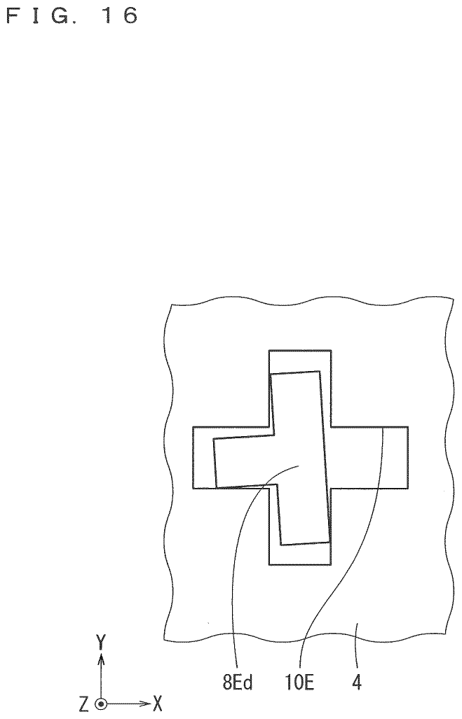

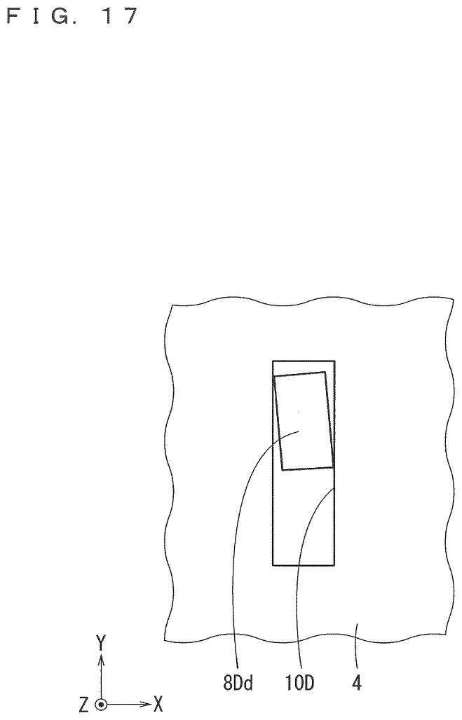

FIG. 16 is a partial plan view illustrating an example of mating of a protrusion 8Ed that corresponds to the protrusion 8E partially missing from any cause with the mating hole 10E. FIG. 17 is a partial plan view illustrating an example of mating of a protrusion 8Dd that corresponds to the protrusion 8D partially missing from any cause with the mating hole 10D. In FIG. 16, missing from the protrusion 8E into the protrusion 8Ed does not significantly affect alignment accuracy. In contrast, in FIG. 17, missing from the protrusion 8D into the protrusion 8Dd is likely to affect alignment accuracy. Specifically, misalignment in the Y direction is likely to increase. When there is large clearance in mating, misalignment in the direction of rotation is likely to increase.

### Embodiment 6

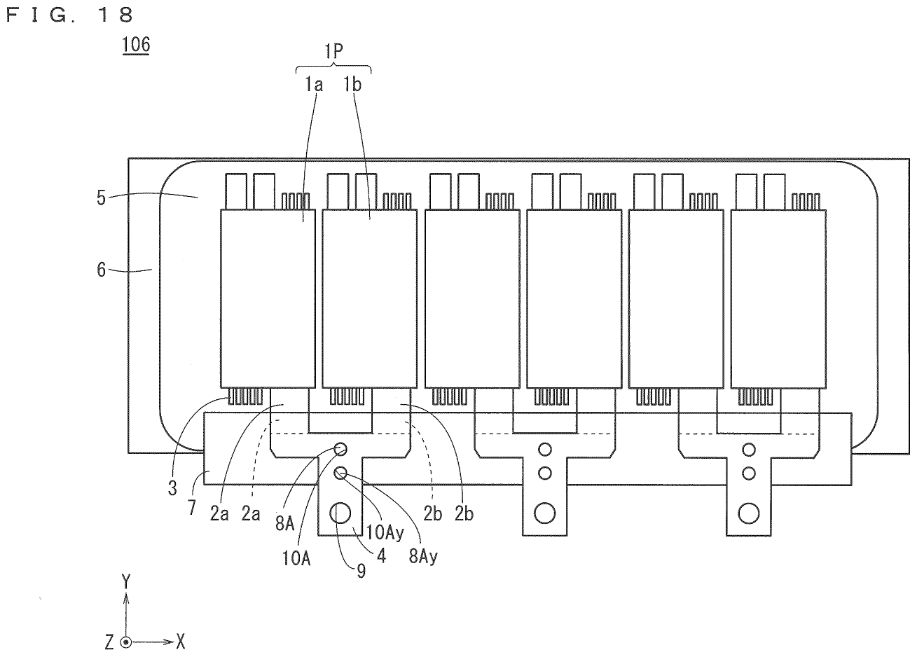

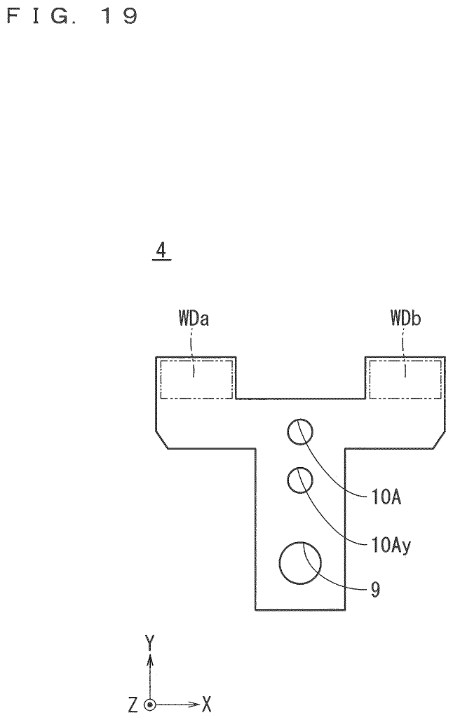

FIG. 18 is a plan view schematically showing a configuration of a semiconductor device 106 according to Embodiment 6. FIG. 19 is a plan view schematically showing a configuration of a metal terminal 4 in FIG. 18. FIG. 19 shows a bonded portion WDa and a bonded portion WDb to respectively be bonded to an output terminal 2a and an output terminal 2b (FIG. 18) by phantom lines (alternate long and two short dashes lines).

In Embodiment 6, the upper surface S2 (see FIG. 2) of the pedestal 7 also has a protrusion 8Ay (second protrusion) away from the protrusion 8A (first protrusion). The metal terminal 4 has not only the mating hole 10A (first mating hole) mating with the protrusion 8A but also a mating hole 10Ay (second mating hole) mating with the protrusion 8Ay. In plan view, the mating hole 10A and the mating hole 10Ay are arranged along the direction parallel to the direction of extension of the output terminal 2a (Y direction). As described above, the metal terminal 4 has the two mating holes, and the pedestal 7 has the two protrusions in one-to-one correspondence with the respective mating holes in Embodiment 6. As a modification, in plan view, three or more mating holes may be arranged along the direction parallel to the direction of extension of the output terminal 2a (Y direction), and the pedestal 7 may have protrusions in one-to-one correspondence with the respective mating holes. A configuration other than the above-mentioned configuration is substantially the same as the above-mentioned configuration according to Embodiment 1, so that the same or corresponding components bear the same reference signs, and description thereof is not repeated.

According to Embodiment 6, the mating hole 10A and the mating hole 10Ay of the metal terminal 4 mate respectively with the protrusion 8A and the protrusion 8Ay of the pedestal 7. Misalignment of the metal terminal 4 in the direction of rotation around one of the protrusion 8A and the protrusion 8Ay is thereby regulated by the other one of the protrusion 8A and the protrusion 8Ay. An insulating distance can thus more stably be secured between the metal terminal 4 electrically connected to the output terminal 2a and the control terminal 3. The metal terminal 4 is not missing in a region between the mating hole 10A and the mating hole 10Ay. The region can thus also contribute as a current path in the metal terminal 4.

### Embodiment 7

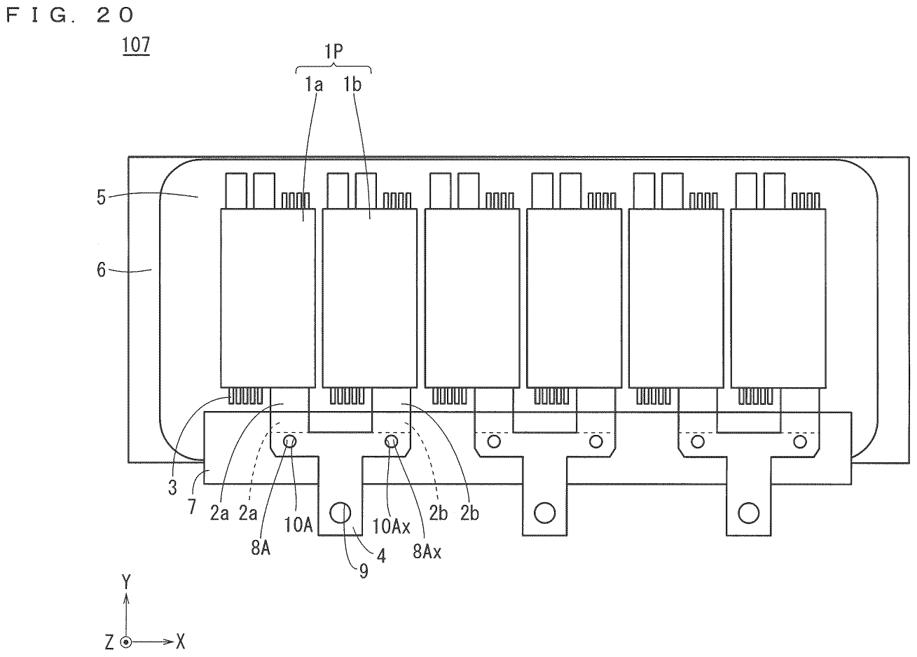

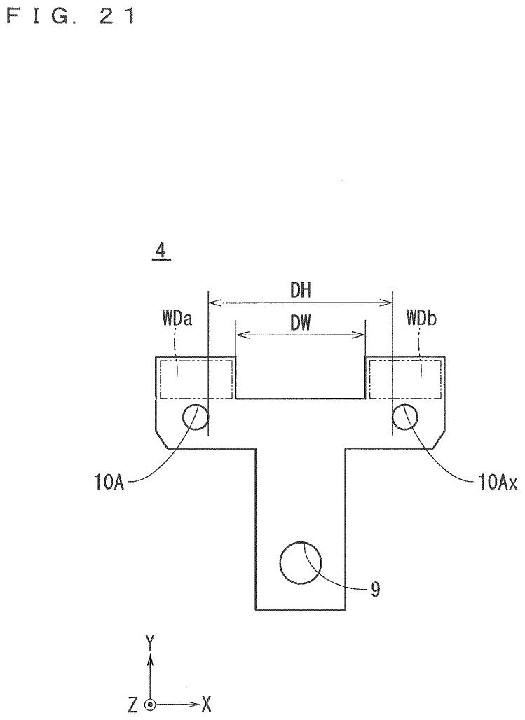

FIG. 20 is a plan view schematically showing a configuration of a semiconductor device 107 according to Embodiment 7. FIG. 21 is a plan view schematically showing a configuration of a metal terminal 4 in FIG. 20. FIG. 21 shows a bonded portion WDa and a bonded portion WDb to respectively be bonded to an output terminal 2a and an output terminal 2b (FIG. 20) by phantom lines (alternate long and two short dashes lines).

In Embodiment 7, the upper surface S2 (see FIG. 2) of the pedestal 7 has the protrusion 8A (first protrusion) and a protrusion 8Ax (second protrusion) away from the protrusion 8A. The metal terminal 4 has the mating hole 10A (first mating hole) mating with the protrusion 8A and a mating hole 10Ax (second mating hole) mating with the protrusion 8Ax. In plan view (FIG. 21), the bonded portion WDa and the bonded portion WDb are separated from each other by a distance DW (first distance) in the orthogonal direction (X direction) orthogonal to the direction of extension of each of the output terminal 2a and the output terminal 2b (Y direction). The mating hole 10A and the mating hole 10Ax are arranged along the orthogonal direction (X direction) and are separated from each other by a distance DH (second distance) in the orthogonal direction (X direction), and the distance DH is greater than the distance DW. A configuration other than the above-mentioned configuration is substantially the same as the above-mentioned configuration according to Embodiment 1, so that the same or corresponding components bear the same reference signs, and description thereof is not repeated.

According to Embodiment 7, the mating hole 10A and the mating hole 10Ax of the metal terminal 4 mate respectively with the protrusion 8A and the protrusion 8Ax of the pedestal 7. Misalignment of the metal terminal 4 in the direction of rotation around one of the protrusion 8A and the protrusion 8Ax is thereby regulated by the other one of the protrusion 8A and the protrusion 8Ax. An insulating distance can thus more stably be secured between the metal terminal 4 electrically connected to the output terminal 2a and the output terminal 2b and the control terminal 3. The metal terminal 4 is not missing in a region between the mating hole 10A and the mating hole 10Ax. The region can thus also contribute as a current path in the metal terminal 4. The distance DH between the mating hole 10A and the mating hole 10Ax is greater than the distance DW between the bonded portion WDa and the second bonded portion WDb. Misalignment in the direction of rotation can thus further be suppressed.

### Embodiment 8

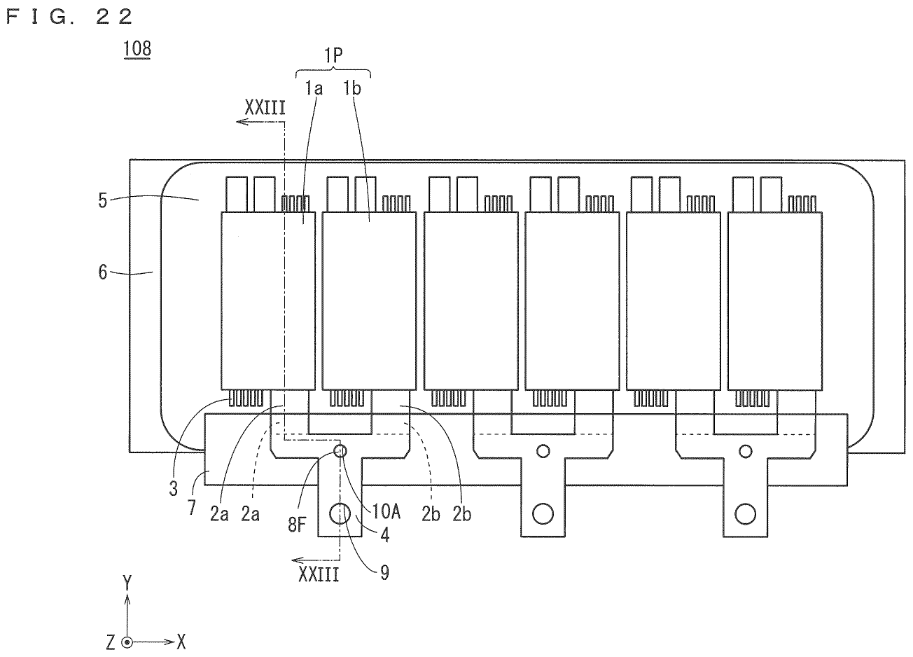

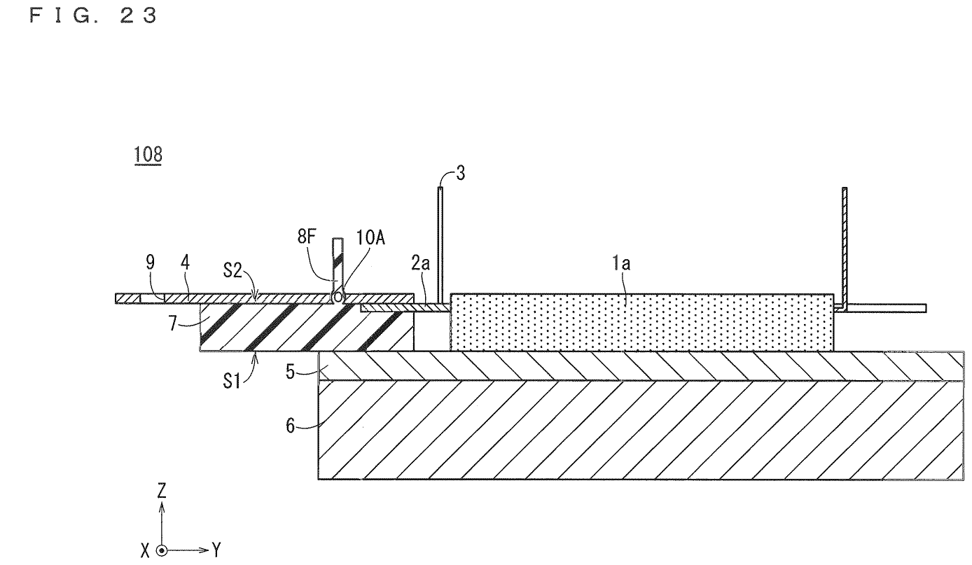

FIG. 22 is a plan view schematically showing a configuration of a semiconductor device 108 according to Embodiment 8. FIG. 23 is a cross-sectional view taken along the line XXIII-XXIII of FIG. 22. In Embodiment 8, a protrusion 8F (the first protrusion) has been press-fitted into the mating hole 10A. In other words, the protrusion 8F has a press-fit structure within the mating hole 10A. In an example shown in FIG. 23, a portion of the protrusion 8F having been inserted into the mating hole 10A has a cavity. The portion of the protrusion 8F within the mating hole 10A thus has high elasticity in the in-plane direction. Due to high elasticity, sufficient press-fit pressure can easily be secured. A configuration other than the above-mentioned configuration is substantially the same as the above-mentioned configuration according to Embodiment 1, so that the same or corresponding components bear the same reference signs, and description thereof is not repeated.

According to Embodiment 8, a similar effect to that obtained in Embodiment 1 described above can be obtained. Furthermore, according to Embodiment 8, the protrusion 8F of the pedestal 7 has been press-fitted into the mating hole 10A of the metal terminal 4. The protrusion 8F is thereby fixed to the mating hole 10A in the height direction. Misalignment of the metal terminal 4 in the height direction is thus prevented in the step of bonding the metal terminal 4. Misalignment of the metal terminal 4 in the height direction can thus also be suppressed.

### Embodiment 9

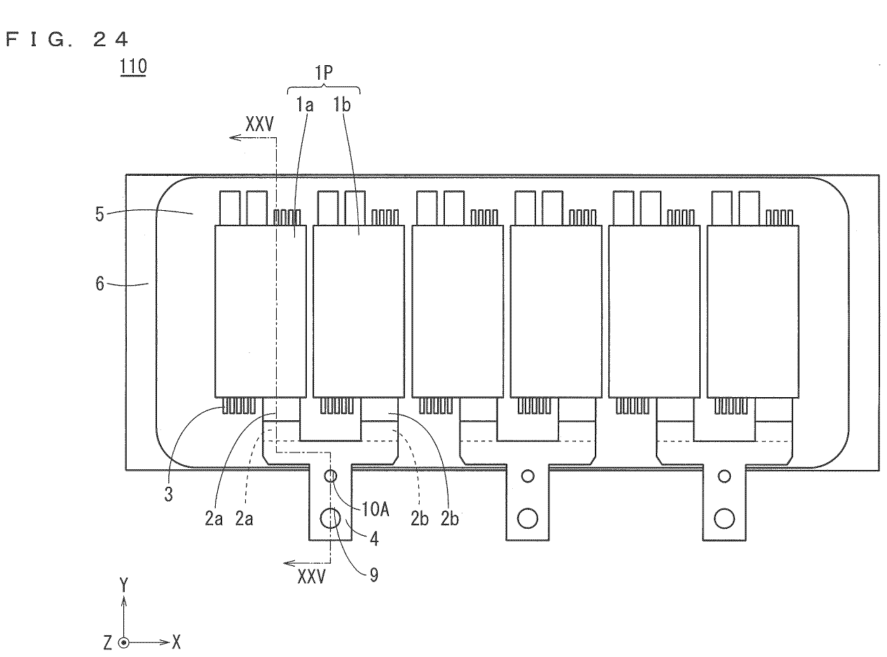

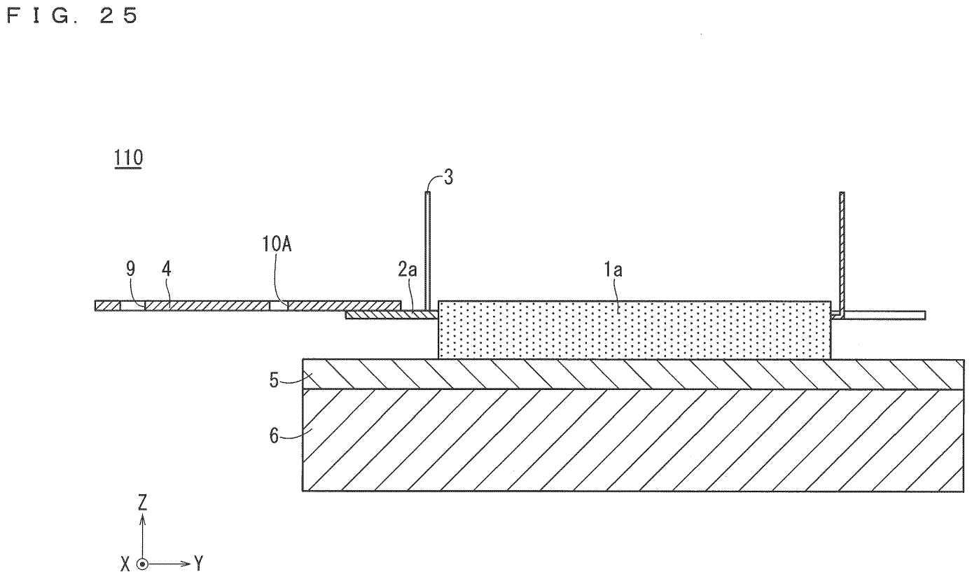

FIG. 24 is a plan view schematically showing a configuration of a semiconductor device 110 according to Embodiment 9. FIG. 25 is a cross-sectional view taken along the line XXV-XXV of FIG. 24. In contrast to the semiconductor device 101 (Embodiment 1) described above, the semiconductor device 110 does not include the pedestal 7. On the other hand, the pedestal 7 is used in a method of manufacturing the semiconductor device 110. This will be described below.

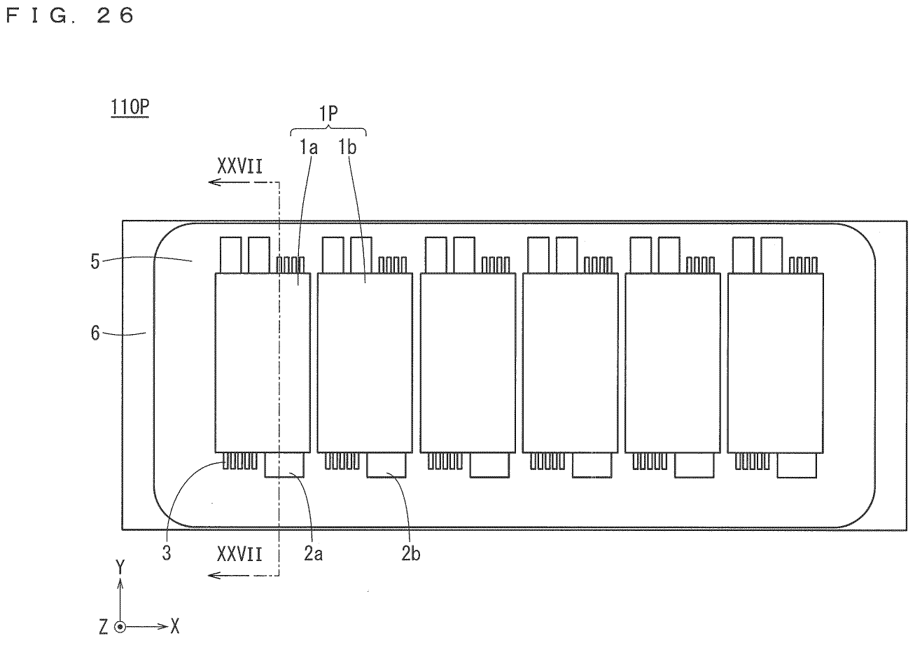

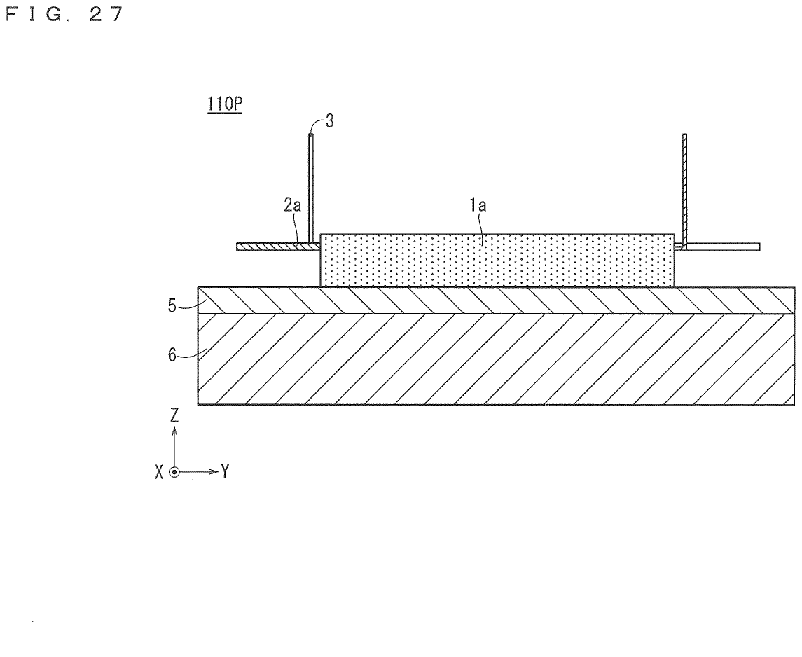

FIG. 26 is a plan view schematically showing a first step of the manufacturing method. FIG. 27 is a cross-sectional view taken along the line XXVII-XXVII of FIG. 26. First, the semiconductor module 1a is disposed over the upper surface of the base plate 5 to form a semi-finished product 110P. Not only the semiconductor module 1a but also the semiconductor module 1b may be disposed. As described in Embodiment 1, the semiconductor module 1a has the control terminal 3 and has the output terminal 2a extending horizontally. The semiconductor module 1b may have a similar configuration.

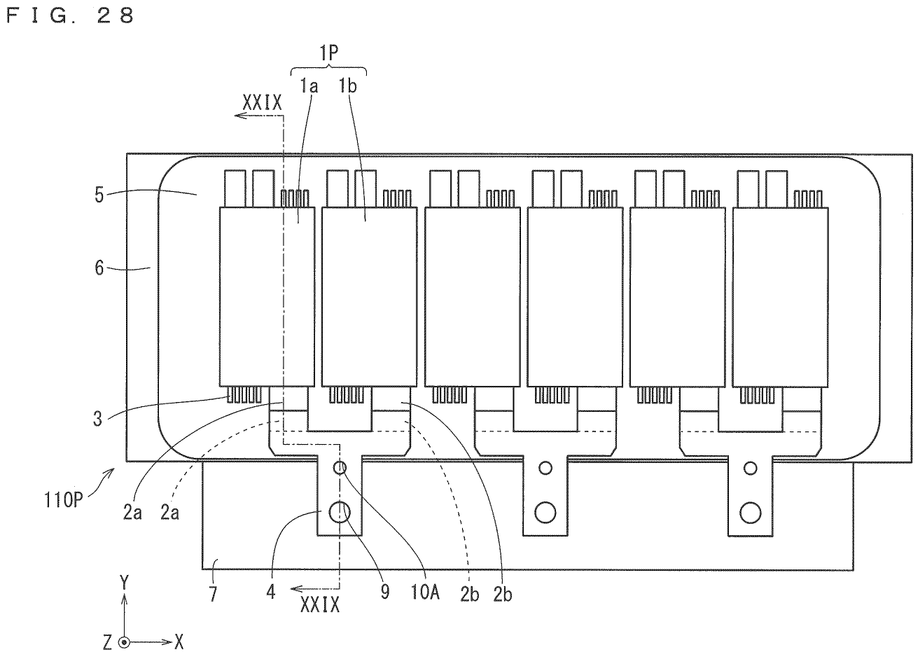

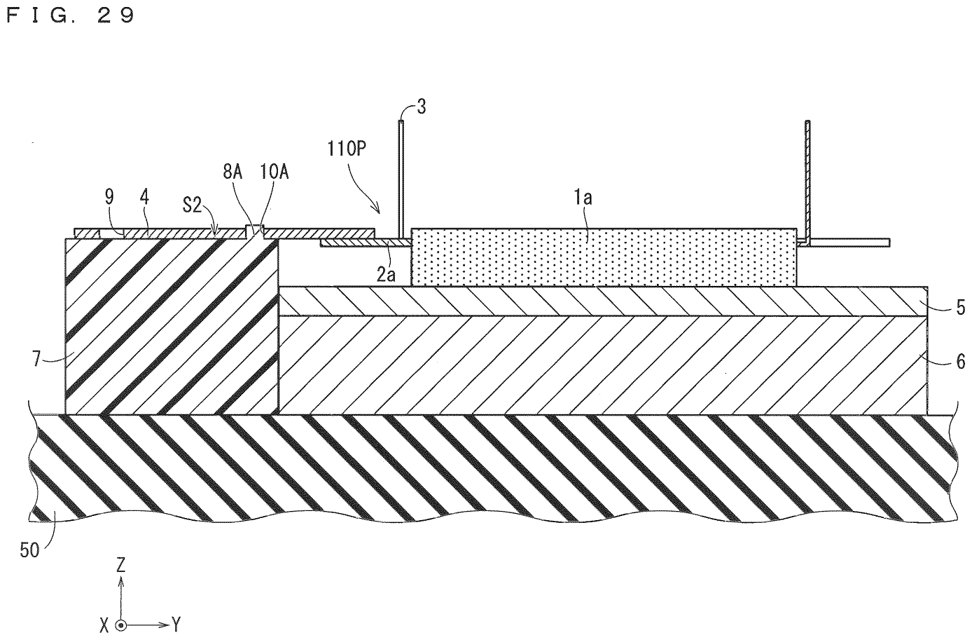

FIG. 28 is a plan view schematically showing a second step of the manufacturing method. FIG. 29 is a cross-sectional view taken along the line XXIX-XXIX of FIG. 28. The metal terminal 4 is disposed to span between the output terminal 2a of the semiconductor module 1a and the pedestal 7 having the protrusion 8A. This step is performed so that a portion of the metal terminal 4 overlaps the output terminal 2a and the mating hole 10A of the metal terminal 4 mates with the protrusion 8A of the pedestal 7. The metal terminal 4 may be disposed also to span between the pedestal 7 and the output terminal 2b of the semiconductor module 1b, so that a portion of the metal terminal 4 overlaps the output terminal 2b. The step of disposing the metal terminal 4 may be performed, with the −Z direction as the direction of gravity, over a workbench 50 having a surface facing in the +Z direction. In this case, the semi-finished product 110P and the pedestal 7 are arranged side by side over a surface of the workbench 50.

Next, the portion of the metal terminal 4 is bonded to the output terminal 2a. The portion of the metal terminal 4 may also be bonded to the output terminal 2b. Bonding is performed by laser welding, for example. The pedestal 7 is then removed. The semiconductor device 110 (FIGS. 24 and 25) is obtained as described above.

According to Embodiment 9, the mating hole 10A of the metal terminal 4 mates with the protrusion 8A of the pedestal 7 when the metal terminal 4 is disposed in the method of manufacturing the semiconductor device 110. The position of the mating hole 10A of the metal terminal 4 is thereby defined in the in-plane direction. Misalignment of the metal terminal 4 in the in-plane direction is thus suppressed. An insulating distance can thus stably be secured between the metal terminal 4 electrically connected to the output terminal 2a and the control terminal 3. While it is more difficult to secure alignment accuracy of the metal terminal 4 especially when the metal terminal 4 is required to be aligned with both of the output terminal 2a and the output terminal 2b, easy securement of the accuracy is facilitated according to Embodiment 9.

### Embodiment 10

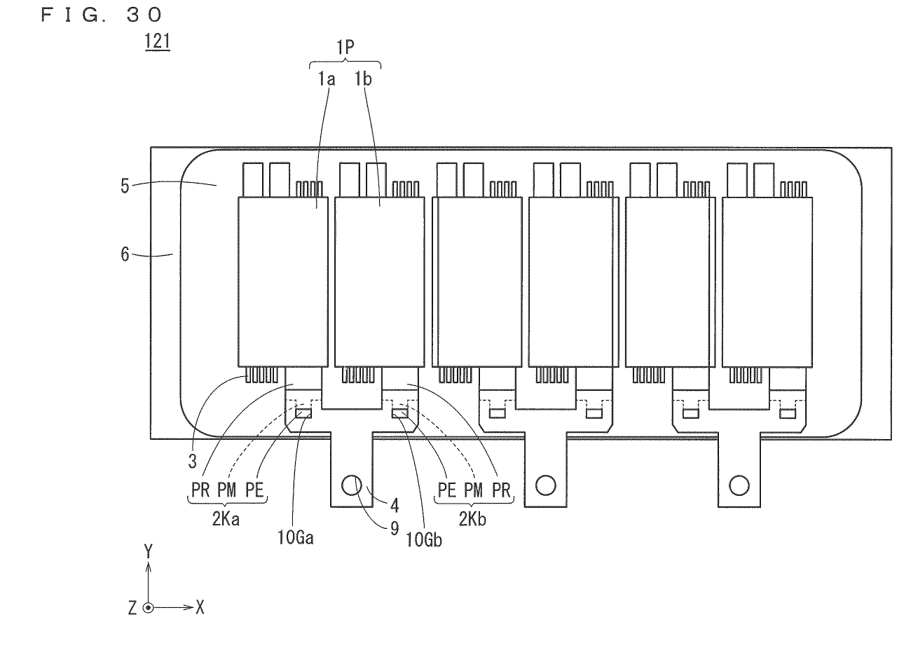

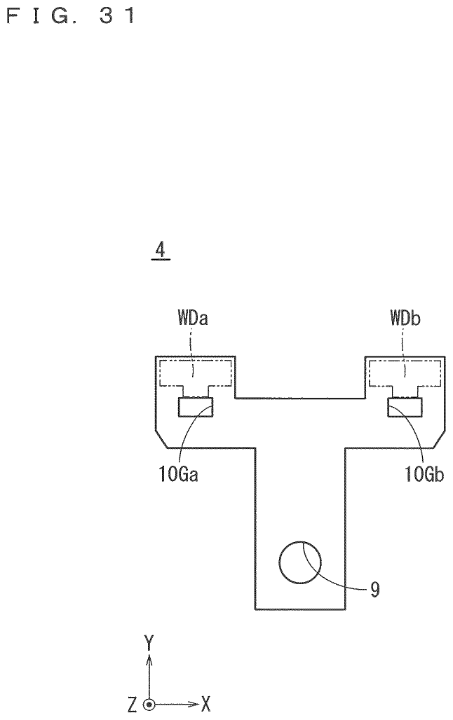

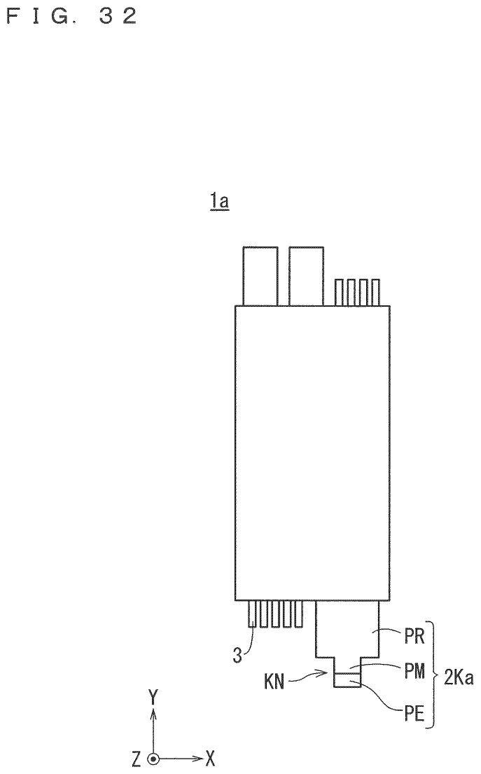

FIG. 30 is a plan view schematically showing a configuration of a semiconductor device 121 according to Embodiment 10. FIG. 31 is a plan view schematically showing a configuration of a metal terminal 4 in FIG. 30. FIG. 31 shows a bonded portion WDa and a bonded portion WDb to respectively be bonded to an output terminal 2Ka and an output terminal 2Kb (FIG. 30) by phantom lines (alternate long and two short dashes lines). FIG. 32 is a plan view schematically showing a configuration of a semiconductor module 1a in FIG. 30. In the semiconductor device 121 and a method of manufacturing the semiconductor device 121, the pedestal is not required in contrast to that according to Embodiments 1 to 9 described above.

In Embodiment 10, the semiconductor module 1a has the output terminal 2Ka (first output terminal) in place of the output terminal 2a (FIG. 1: Embodiment 1). The output terminal 2Ka has a root portion PR extending horizontally from an insulating package (a portion shown by a rectangle in FIG. 32) of the semiconductor module 1a and a tip portion PE extending to have a smaller width (dimension in the X direction) than the root portion PR. As illustrated in FIG. 32, the output terminal 2Ka may further have an intermediate portion PM between the root portion PR and the tip portion PE. The intermediate portion PM extends horizontally similarly to the root portion PR and has a smaller width than the root portion PR similarly to the tip portion PE. The intermediate portion PM may have substantially the same width as the tip portion PE. The output terminal 2Ka has been bent between the root portion PR and the tip portion PE so that the tip portion PE extends non-horizontally. Specifically, the output terminal 2Ka may have been bent between the tip portion PE and the intermediate portion PM. The tip portion PE may extend in the height direction (Z direction). Specifically, the tip portion PE may extend in the +Z direction from the root portion PR or the intermediate portion PM. The semiconductor module 1b may have the output terminal 2Kb (second output terminal) having a similar configuration to the output terminal 2Ka of the semiconductor module 1a.

The metal terminal 4 has the bonded portion WDa (FIG. 31) bonded to the root portion PR (FIG. 32) of the output terminal 2Ka. The bonded portion WDa may be bonded to the intermediate portion PM (FIG. 32). The metal terminal 4 also has a mating hole 10Ga (FIG. 30) mating with the tip portion PE of the output terminal 2Ka. Similarly, the metal terminal 4 may have the bonded portion WDb (FIG. 31) bonded to the root portion PR (FIG. 32) of the output terminal 2Kb. The bonded portion WDb may be bonded to the intermediate portion PM. The metal terminal 4 may also have a mating hole 10Gb (FIG. 30) mating with the tip portion PE of the output terminal 2Kb.

A configuration other than the above-mentioned configuration is substantially the same as the above-mentioned configuration according to Embodiment 1, so that the same or corresponding components bear the same reference signs, and description thereof is not repeated.

According to Embodiment 10, the metal terminal 4 has the mating hole 10Ga mating with the tip portion PE of the output terminal 2Ka. The position of the mating hole 10Ga of the metal terminal 4 is thereby defined in the in-plane direction. Misalignment of the metal terminal 4 in the in-plane direction is thus suppressed. An insulating distance can thus stably be secured between the metal terminal 4 electrically connected to the output terminal 2Ka and the control terminal 3. While it is more difficult to secure alignment accuracy of the metal terminal 4 especially when the metal terminal 4 is required to be aligned with both of the output terminal 2a and the output terminal 2b, easy securement of the accuracy is facilitated according to Embodiment 10.

According to Embodiment 10, the pedestal is not required in contrast to that according to Embodiments 1 to 8 described above. The number of members can thus be reduced. Furthermore, a step of removing the pedestal is not required in contrast to that according to Embodiment 9 described above. The number of steps can thus be reduced.

### Embodiment 11

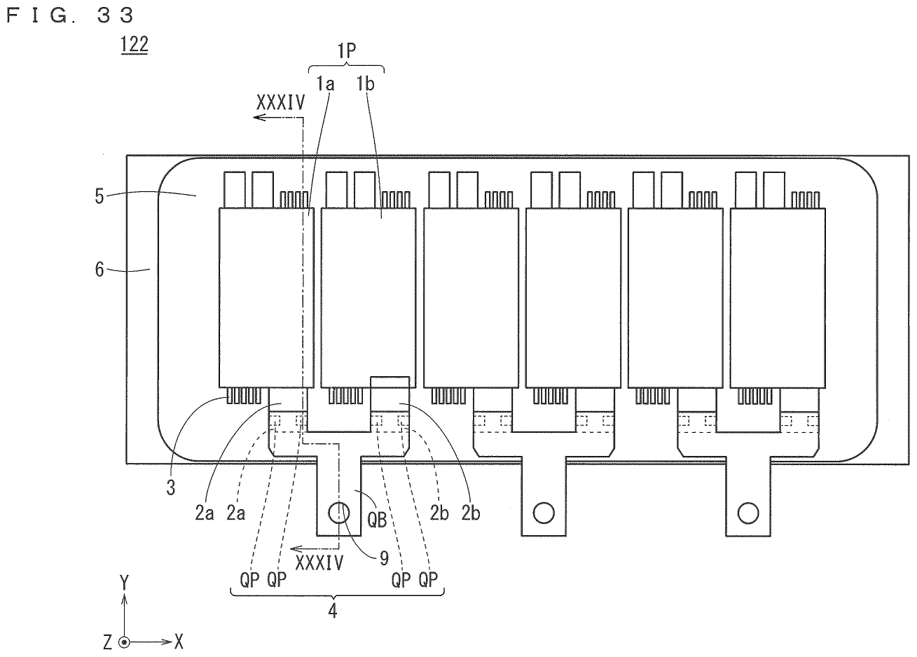

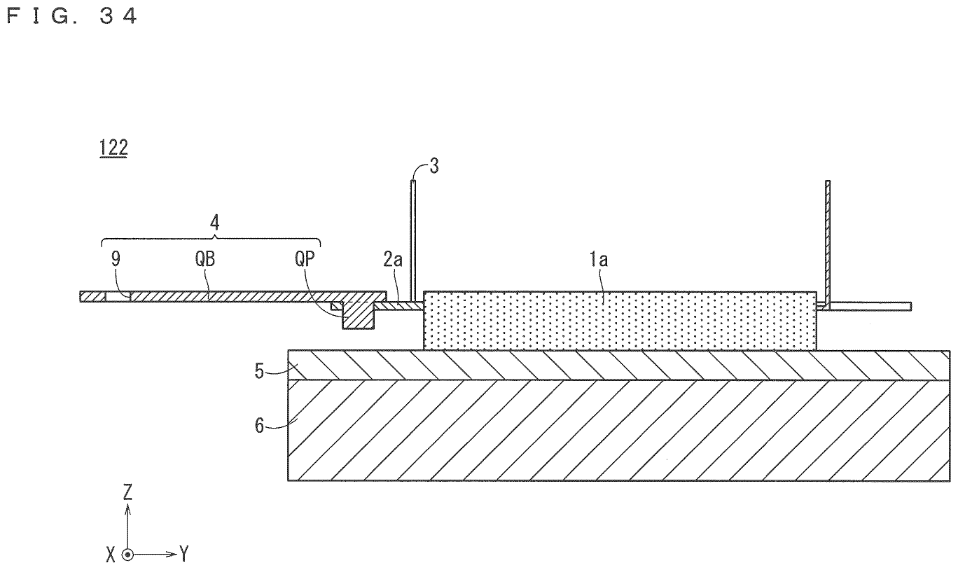

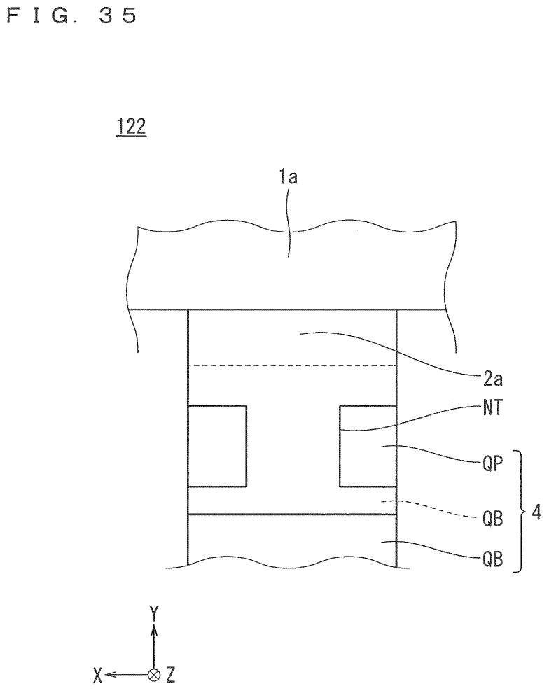

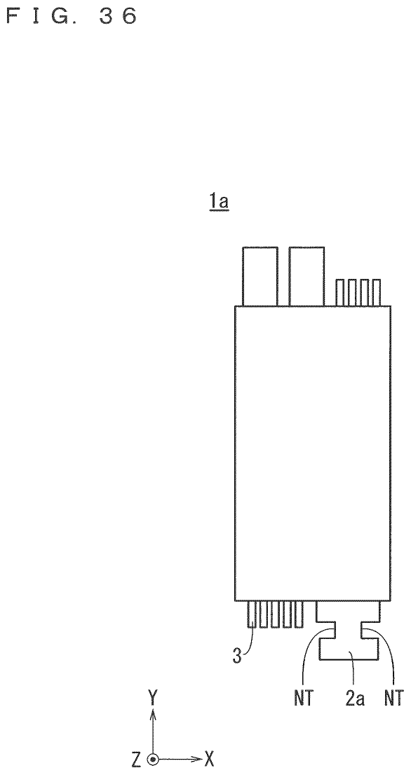

FIG. 33 is a plan view schematically showing a configuration of a semiconductor device 122 according to Embodiment 11. FIG. 34 is a cross-sectional view taken along the line XXXIV-XXXIV of FIG. 33. FIG. 35 is a partial bottom view of the semiconductor device 122. FIG. 36 is a plan view schematically showing a configuration of a semiconductor module 1a of the semiconductor device 122. In the semiconductor device 122 and a method of manufacturing the semiconductor device 122, the pedestal is not required in contrast to that according to Embodiments 1 to 9 described above.

In Embodiment 11 and Embodiment 12, which will be described below, the output terminal 2a and the metal terminal 4 have a mating structure. This mating structure includes cutouts NT in plan view and protrusions QP mating with the cutouts NT. The protrusions QP protrude from a flat portion QB in the height direction (Z direction). In particular, in the semiconductor device 122 according to Embodiment 11, as the mating structure, the output terminal 2a has the cutouts NT, and the metal terminal 4 has the protrusions QP protruding in the −Z direction. In the method of manufacturing the semiconductor device 122, after the metal terminal 4 is disposed over the output terminal 2a using this mating structure, they are bonded together. The output terminal 2b of the semiconductor module 1b may have cutouts similar to the cutouts NT of the output terminal 2a. In this case, the metal terminal 4 has not only the protrusions QP mating with the cutouts NT of the output terminal 2a but also protrusions QP mating with the cutouts of the output terminal 2b.

A configuration other than this configuration is substantially the same as the above-mentioned configuration according to Embodiment 1, so that the same or corresponding components bear the same reference signs, and description thereof is not repeated.

According to Embodiment 11, the output terminal 2a and the metal terminal 4 have the mating structure including the cutouts NT in plan view and the protrusions QP mating with the cutouts NT. The position of the metal terminal 4 is thereby defined in the in-plane direction. Misalignment of the metal terminal 4 in the in-plane direction is thus suppressed. An insulating distance can thus stably be secured between the metal terminal 4 electrically connected to the output terminal 2a and the control terminal 3. While it is more difficult to secure alignment accuracy of the metal terminal 4 especially when the metal terminal 4 is required to be aligned with both of the output terminal 2a and the output terminal 2b, easy securement of the accuracy is facilitated according to Embodiment 11.

According to Embodiment 11, the pedestal is not required in contrast to that according to Embodiments 1 to 8 described above. The number of members can thus be reduced. Furthermore, the step of removing the pedestal is not required in contrast to that according to Embodiment 9 described above. The number of steps can thus be reduced.

### Embodiment 12

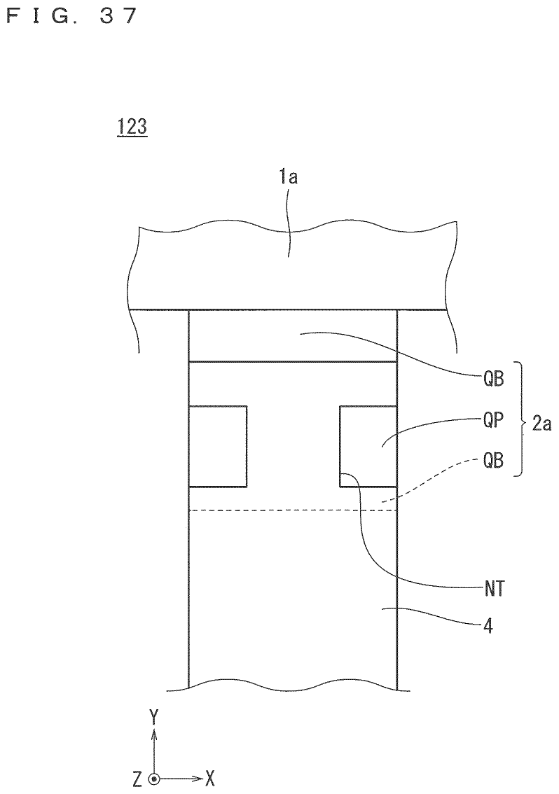

FIG. 37 is a partial plan view schematically showing a configuration of a semiconductor device 123 according to Embodiment 12. In Embodiment 12, a mating structure similar to the above-mentioned mating structure according to Embodiment 11 is provided. In the semiconductor device 123 according to Embodiment 12, however, the metal terminal 4 has cutouts NT and the output terminal 2a has protrusions QP protruding in the +Z direction as the mating structure in contrast to those in the semiconductor device 122 (FIG. 35: Embodiment 11). In the method of manufacturing the semiconductor device 123, after the metal terminal 4 is disposed over the output terminal 2a using this mating structure, they are bonded together. The output terminal 2b of the semiconductor module 1b may have protrusions similar to the protrusions QP of the output terminal 2a. In this case, the metal terminal 4 has not only the cutouts NT mating with the protrusions QP of the output terminal 2a but also cutouts mating with the protrusions of the output terminal 2b. A configuration other than this configuration is substantially the same as the above-mentioned configuration according to Embodiment 11, so that the same or corresponding components bear the same reference signs, and description thereof is not repeated.

Embodiments can freely be combined with each other and can be modified or omitted as appropriate.

### APPENDICES

Various aspects of the present disclosure will collectively be described below as appendices.

### Appendix 1

A semiconductor device (101-108) comprising:
a base plate (5) having an upper surface;
at least one semiconductor module (1a, 1b) disposed over the upper surface of the base plate (5) and having a control terminal (3) and a first output terminal (2a), the first output terminal (2a) extending horizontally;
a pedestal (7) disposed over the upper surface of the base plate (5) and having a first surface (S1) and a second surface (S2), the first surface (S1) facing the upper surface of the base plate (5), the second surface (S2) being opposite the first surface (S1) and having a first protrusion (8A-8F); and
a metal terminal (4) having a first bonded portion (WDa) bonded to the first output terminal (2a) of the at least one semiconductor module (1a, 1b) and having a first mating hole (10A-10E) mating with the first protrusion (8A-8E) of the pedestal (7).

### Appendix 2

The semiconductor device (102-104) according to Appendix 1, wherein
in plan view,
   the first protrusion (8B-8D) of the pedestal (7) has a shape corresponding to a shape of the first mating hole (10B-10D) of the metal terminal (4), and
   the first mating hole (10B-10D) has an elliptical shape having a major axis or a rectangular shape having a longer side.

### Appendix 3

The semiconductor device (103, 104) according to Appendix 1, wherein
in plan view,
   the first output terminal (2a) extends along a direction of extension,
   the first protrusion (8C, 8D) of the pedestal (7) has a shape corresponding to a shape of the first mating hole (10C, 10D) of the metal terminal (4), and
   the first mating hole (10C, 10D) has an elliptical shape having a major axis along a direction parallel to the direction of extension or a rectangular shape having a longer side along a direction parallel to the direction of extension.

### Appendix 4

The semiconductor device (105) according to Appendix 1, wherein
in plan view,
   the first protrusion (8E) of the pedestal (7) has a shape corresponding to a shape of the first mating hole (10E), and
   the first mating hole (10E) of the metal terminal (4) has a cruciform shape.

### Appendix 5

The semiconductor device (106) according to any one of Appendices 1 to 4, wherein
the second surface (S2) of the pedestal (7) has a second protrusion (8Ay) away from the first protrusion (8A), and the metal terminal (4) has a second mating hole (10Ay) mating with the second protrusion (8Ay) of the pedestal (7), and
in plan view,
   the first output terminal (2a) extends along a direction of extension, and
   the first mating hole (10A) and the second mating hole (10Ay) are arranged along a direction parallel to the direction of extension.

### Appendix 6

The semiconductor device (107) according to any one of Appendices 1 to 4, wherein
the at least one semiconductor module (1a, 1b) has a second output terminal (2b) extending horizontally,
the second surface (S2) of the pedestal (7) has a second protrusion (8Ax),
the metal terminal (4) has a second mating hole (10Ax) mating with the second protrusion (8Ax) of the pedestal (7) and has a second bonded portion (WDb) bonded to the second output terminal (2b) of the at least one semiconductor module (1a, 1b) and a branching portion having a shape branching to the first bonded portion (WDa) and the second bonded portion (WDb), and
in plan view,
   the first output terminal (2a) and the second output terminal (2b) each extend along a direction of extension,
   the first bonded portion (WDa) and the second bonded portion (WDb) are separated from each other by a first distance (DW) in an orthogonal direction orthogonal to the direction of extension, and
   the first mating hole (10A) and the second mating hole (10Ax) are arranged along the orthogonal direction and are separated from each other by a second distance (DH) in the orthogonal direction, and the second distance (DH) is greater than the first distance (DW).

### Appendix 7

The semiconductor device (108) according to any one of Appendices 1 to 6, wherein
the first protrusion (8F) is press-fitted into the first mating hole (10A).

### Appendix 8

A semiconductor device (121) comprising:
a base plate (5) having an upper surface;
a semiconductor module (1a, 1b) disposed over the upper surface of the base plate (5) and having a control terminal (3) and an output terminal (2Ka), the output terminal (2Ka) having a root portion (PR) extending horizontally and a tip portion (PE) extending to have a smaller width than the root portion (PR), the output terminal (2Ka) being bent between the root portion (PR) and the tip portion (PE) so that the tip portion (PE) extends non-horizontally; and
a metal terminal (4) having a bonded portion (WDa) bonded to the root portion (PR) of the output terminal (2Ka) of the semiconductor module (1a, 1b), the metal terminal (4) having a mating hole (10Ga) mating with the tip portion (PE) of the output terminal (2Ka).

### Appendix 9

A semiconductor device (122, 123) comprising:
a base plate (5) having an upper surface;
a semiconductor module (1a, 1b) disposed over the upper surface of the base plate (5) and having a control terminal (3) and an output terminal (2a); and
a metal terminal (4) having a bonded portion (WDa) bonded to the output terminal (2a) of the semiconductor module (1a, 1b), wherein
the output terminal (2a) and the metal terminal (4) have a mating structure including a cutout (NT) in plan view and a protrusion (QP) mating with the cutout (NT), and one of the output terminal (2a) and the metal terminal (4) has the cutout (NT) and the other one of the output terminal (2a) and the metal terminal (4) has the protrusion (QP).

### Appendix 10

A method of manufacturing a semiconductor device (110), the method comprising:
disposing a semiconductor module (1a, 1b) over an upper surface of a base plate (5), the semiconductor module (1a, 1b) having a control terminal (3) and an output terminal (2a), the output terminal (2a) extending horizontally;
disposing a metal terminal (4) so that the metal terminal (4) spans between the output terminal (2a) of the semiconductor module (1a, 1b) and a pedestal (7) having a protrusion (8A), the metal terminal (4) being disposed so that a portion of the metal terminal (4) overlaps the output terminal (2a) and a mating hole of the metal terminal (4) mates with the protrusion (8A) of the pedestal (7);
bonding the portion of the metal terminal (4) to the output terminal; and
removing the pedestal (7) after bonding the portion of the metal terminal (4).

While the disclosure has been shown and described in detail, the foregoing description is in all aspects illustrative and not restrictive. It is therefore understood that numerous modifications and variations can be devised.

What is claimed is:

1. A semiconductor device comprising:
a base plate having an upper surface;
at least one semiconductor module disposed over the upper surface of the base plate and having a control terminal and a first output terminal, the first output terminal extending horizontally;
a pedestal disposed over the upper surface of the base plate and having a first surface and a second surface, the first surface facing the upper surface of the base plate, the second surface being opposite the first surface and having a first protrusion; and
a metal terminal having a first bonded portion bonded to the first output terminal of the at least one semiconductor module and having a first mating hole mating with the first protrusion of the pedestal.

2. The semiconductor device according to claim 1, wherein
in plan view,
the first protrusion of the pedestal has a shape corresponding to a shape of the first mating hole of the metal terminal, and
the first mating hole has an elliptical shape having a major axis or a rectangular shape having a longer side.

3. The semiconductor device according to claim 1, wherein
in plan view,
the first output terminal extends along a direction of extension,
the first protrusion of the pedestal has a shape corresponding to a shape of the first mating hole of the metal terminal, and
the first mating hole has an elliptical shape having a major axis along a direction parallel to the direction of extension or a rectangular shape having a longer side along a direction parallel to the direction of extension.

4. The semiconductor device according to claim 1, wherein
in plan view,
the first protrusion of the pedestal has a shape corresponding to a shape of the first mating hole, and
the first mating hole of the metal terminal has a cruciform shape.

5. The semiconductor device according to claim 1, wherein
the second surface of the pedestal has a second protrusion away from the first protrusion, and the metal terminal has a second mating hole mating with the second protrusion of the pedestal, and
in plan view,
the first output terminal extends along a direction of extension, and
the first mating hole and the second mating hole are arranged along a direction parallel to the direction of extension.

6. The semiconductor device according to claim 1, wherein
the at least one semiconductor module has a second output terminal extending horizontally,
the second surface of the pedestal has a second protrusion,
the metal terminal has a second mating hole mating with the second protrusion of the pedestal and has a second bonded portion bonded to the second output terminal of the at least one semiconductor module and a branching portion having a shape branching to the first bonded portion and the second bonded portion, and
in plan view,
the first output terminal and the second output terminal each extend along a direction of extension,
the first bonded portion and the second bonded portion are separated from each other by a first distance in an orthogonal direction orthogonal to the direction of extension, and
the first mating hole and the second mating hole are arranged along the orthogonal direction and are separated from each other by a second distance in the orthogonal direction, and the second distance is greater than the first distance.

7. The semiconductor device according to claim 1, wherein
the first protrusion is press-fitted into the first mating hole.

8. A semiconductor device comprising:
a base plate having an upper surface;
a semiconductor module disposed over the upper surface of the base plate and having a control terminal and an output terminal, the output terminal having a root portion extending horizontally and a tip portion extending to have a smaller width than the root portion, the output terminal being bent between the root portion and the tip portion so that the tip portion extends non-horizontally; and
a metal terminal having a bonded portion bonded to the root portion of the output terminal of the semiconductor module, the metal terminal having a mating hole mating with the tip portion of the output terminal.

9. A semiconductor device comprising:
a base plate having an upper surface;
a semiconductor module disposed over the upper surface of the base plate and having a control terminal and an output terminal; and
a metal terminal having a bonded portion bonded to the output terminal of the semiconductor module, wherein
the output terminal and the metal terminal have a mating structure including a cutout in plan view and a protrusion mating with the cutout, and one of the output terminal and the metal terminal has the cutout and the other one of the output terminal and the metal terminal has the protrusion.

10. A method of manufacturing a semiconductor device, the method comprising:
disposing a semiconductor module over an upper surface of a base plate, the semiconductor module having a control terminal and an output terminal, the output terminal extending horizontally;
disposing a metal terminal so that the metal terminal spans between the output terminal of the semiconductor module and a pedestal having a protrusion, the metal terminal being disposed so that a portion of the metal terminal overlaps the output terminal and a mating hole of the metal terminal mates with the protrusion of the pedestal;
bonding the portion of the metal terminal to the output terminal; and
removing the pedestal after bonding the portion of the metal terminal.
